(19) United States
(12) Patent Application Publication
(10) Pub. No.: US 2026/0255961 A1
(43) Pub. Date: Aug. 27, 2026

(54) PHOTONIC OR ELECTRONIC CHIPS OR CHIPLETS WITH THERMALLY CONDUCTIVE LIDS INCLUDING WIDE-BANDGAP MATERIALS FOR ADVANCED PACKAGING

(71) Applicant: Samsung Electronics Co., Ltd., Suwon-si (KR)

(72) Inventors: Yan Li, Morgan Hill, CA (US); WooPoung Kim, San Jose, CA (US)

(21) Appl. No.: 19/362,996

(22) Filed: Oct. 20, 2025

Related U.S. Application Data
(60) Provisional application No. 63/763,535, filed on Feb. 26, 2025.

(51) Int. Cl. H10W 40/25; G02B 6/42; H10W 90/00; H10W 20/41; H10W 40/43; H10W 40/47

(52) U.S. Cl. CPC H10W 40/255; G02B 6/4268; H10W 40/253; H10W 40/254; H10W 40/259; H10W 90/00; H10W 20/427; H10W 40/43; H10W 40/47

(57) ABSTRACT

An integrated circuit device includes a semiconductor die having an active layer between opposing first and second surfaces, and a thermally conductive lid on the semiconductor die. The thermally conductive lid includes a first layer of a first material on the first surface of the semiconductor die, and a second layer of a second material on the first layer opposite the first surface. The first material has a wider bandgap than the second material. The first material may be a wide-bandgap material such as diamond, and the second material may be a semiconductor material such as silicon. Related packages and fabrication methods are also discussed.

### CLAIM OF PRIORITY

This application claims priority from U.S. Provisional Patent Application Serial No. 63/763,535 entitled “GLASS OR SI SUBSTRATES EMBEDDED WITH SI-SCD BONDED PHOTONIC OR ELECTRONIC CHIPLETS WITH BSPDN FOR ADVANCED PACKAGING,” filed February 26, 2025, with the United States Patent and Trademark Office, the disclosure of which is incorporated by reference herein in its entirety.

### TECHNICAL FIELD

The present disclosure relates to integrated circuit devices, packages, and methods of forming the same.

### BACKGROUND

The rapid evolution of modern electronics and computing systems has led to increased demand for semiconductor devices with improved performance, functionality, and integration density. As scaling of transistor geometries approaches physical and economic limits, advanced packaging technologies have been proposed for continuing performance improvements in electronic systems.

### SUMMARY

Some embodiments of the present disclosure may be directed to integrated circuit devices and packages that include diamond (or other wide-bandgap semiconductor or insulator material) to help with thermal management. For example, an electronic or photonic integrated circuit chip or chiplet may be bonded to a diamond (or other wide-bandgap semiconductor or insulator material) layer as a thermally conductive lid, and may be embedded in a package substrate (such as a glass or Si substrate). The thermally conductive lid may not include (i.e., may be free of) electrical connections (such as through diamond vias) therein, and may provide improved heat dissipation. In some embodiments, the thermally conductive lid may include one or more additional layers, to reduce the thickness (and associated cost) of the diamond (or other wide-bandgap semiconductor or insulator material) layer. The additional layer(s) may include the same semiconductor material as the chips or chiplets, for process compatibility.

According to some embodiments, an integrated circuit device comprises a semiconductor die having an active layer between opposing first and second surfaces, and a thermally conductive lid that is external to the semiconductor die. The thermally conductive lid comprises a first layer of a first material on the first surface of the semiconductor die and a second layer of a second material on the first layer opposite the first surface, where the first material has a wider bandgap than the second material.

In some embodiments, the thermally conductive lid is free of electrical connections therein.

In some embodiments, the first material includes a wide-bandgap material, and the second material includes a semiconductor material.

In some embodiments, the wide-bandgap material layer is bonded to the first surface of the semiconductor die with a first bonding interface therebetween, and the semiconductor material layer is bonded to a surface of the wide-bandgap material layer with a second bonding interface therebetween.

In some embodiments, the second bonding interface comprises wafer-on-wafer bonding interface.

In some embodiments, the first bonding interface comprises one of a die-on-wafer bonding interface or a wafer-on-wafer bonding interface.

In some embodiments, the first material includes diamond, aluminum nitride, boron nitride, gallium nitride, or silicon carbide, and the second material includes glass, silicon, gallium nitride, or silicon carbide. The first material may include single-crystal diamond, and the second material may include silicon.

In some embodiments, a surface of the active layer may be a first distance from the first surface and may be a second distance from the second surface, where the first distance is smaller than the second distance.

In some embodiments, the semiconductor die ( or the active layer thereof) comprises the second material.

In some embodiments, the first layer has a first thickness of about 2 µm to about 100 µm, and the second layer has a second thickness of about 50 µm to about 700 µm.

In some embodiments, the a semiconductor die that further includes a backside power delivery network adjacent to the second surface thereof.

In some embodiments, the semiconductor die further comprises a memory chip between the backside power delivery network and the thermally conductive lid structure.

In some embodiments, the semiconductor die comprises a photonic integrated circuit (PIC) or an electronic integrated circuit (EIC).

According to some embodiments, an integrated circuit device package comprises a package substrate and an integrated circuit device adjacent a surface of the package substrate. The integrated circuit device comprises a semiconductor die having an active layer between opposing first and second surfaces, and a thermally conductive lid that is external to the semiconductor die. The thermally conductive lid comprises a first layer of a first material on the first surface of the semiconductor die and a second layer of a second material on the first layer opposite the first surface. The first material has a wider bandgap than the second material, and the semiconductor die is between the thermally conductive lid and the surface of the package substrate.

In some embodiments, the integrated circuit device may be attached to the surface of the package substrate. For example, a second surface of the semiconductor die may be attached to the surface of the package substrate, and a first surface of the semiconductor die having the thermally conductive lid thereon may be opposite the surface of the package substrate.

In some embodiments, the integrated circuit device may be embedded in the package substrate below the surface thereof.

In some embodiments, the package substrate further comprises one or more redistribution layers on the second surface of the semiconductor die, where the one or more redistribution layers comprise conductive lines and vias. The semiconductor die and the conductive lines and vias are electrically connected to first and second components that are attached to the surface of the package substrate.

In some embodiments, the integrated circuit device package further comprises liquid cooling channels and/or thermal vias in the package substrate extending under or adjacent to the integrated circuit device.

In some embodiments, the integrated circuit device package further comprises an integrated stacked capacitor in the package substrate below the surface thereof.

In some embodiments, the semiconductor die that includes a photonic integrated circuit, and the package further comprises a fiber optic array unit that is optically coupled to the photonic integrated circuit at the second surface of the semiconductor die.

In some embodiments, the one or more redistribution layers comprise an opening therein, and the fiber optic array unit extends through the opening to contact the second surface of the semiconductor die.

In some embodiments, the semiconductor die further comprises a backside power delivery network adjacent to the second surface.

In some embodiments, the package substrate includes glass and/or silicon. In some embodiments, the package substrate includes an organic material.

In some embodiments, a second integrated circuit device is attached to a bottom surface of the package substrate opposite the top surface.

According to some embodiments, a method of fabricating an integrated circuit device package comprises forming a thermally conductive lid layer by bonding a first layer of a first material to a second layer of a second material, where the first material has a wider bandgap than the second material, and providing the thermally conductive lid layer on a semiconductor wafer comprising an active layer between opposing first and second surfaces, where the first layer is on the first surface of the semiconductor wafer and the second layer is on the first layer opposite the first surface.

In some embodiments, the first material comprises a wide-bandgap material having an energy bandgap of greater than about 2 electron-volts, and the second material comprises a semiconductor material.

In some embodiments, the first material comprises single-crystal diamond, and the second material comprises silicon.

In some embodiments, providing the thermally conductive lid on the semiconductor wafer comprises bonding the first layer of the thermally conductive lid to the first surface of the semiconductor wafer along a first bonding interface therebetween, and further comprises singulating the semiconductor wafer having the thermally conductive lid layer thereon to form a plurality of semiconductor dies having respective thermally conductive lids thereon.

In some embodiments, the first bonding interface is a wafer-on-wafer bonding interface.

In some embodiments, providing the thermally conductive lid on the semiconductor wafer comprises singulating the thermally conductive lid layer into respective thermally conductive lids, bonding the respective thermally conductive lids to respective portions of the first surface of the semiconductor wafer along respective first bonding interfaces therebetween, and singulating the semiconductor wafer having the respective thermally conductive lids thereon to form a plurality of semiconductor dies having the respective thermally conductive lids thereon.

In some embodiments, the first bonding interface is a die-on-wafer bonding interface.

In some embodiments, the semiconductor wafer comprises a first wafer having a backside power delivery network adjacent the second surface.

In some embodiments, the semiconductor wafer further comprises a second wafer stacked on the first wafer, where the second wafer comprises a plurality of memory cell transistors between the backside power delivery network and the thermally conductive lid layer.

In some embodiments, the method further includes singulating the semiconductor wafer to provide an integrated circuit device comprising a semiconductor die having a thermally conductive lid thereon, and providing the integrated circuit device adjacent to a surface of a package substrate

In some embodiments, providing the integrated circuit device adjacent the surface of the package substrate comprises attaching the integrated circuit device to the surface of the package substrate.

In some embodiments, providing the integrated circuit device adjacent the surface of the package substrate comprises embedding the integrated circuit device in the package substrate below the surface thereof.

In some embodiments, embedding the integrated circuit device in the package substrate comprises recessing the surface of the package substrate to form a cavity extending below the surface, and attaching the integrated circuit device to the package substrate in the cavity.

In some embodiments, the method further comprises forming liquid cooling channels and/or thermal vias extending under or adjacent the cavity in the package substrate.

In some embodiments, the integrated circuit device package further comprises embedding an integrated stacked capacitor in the package substrate below the surface thereof.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the present disclosure, and be protected by the accompanying claims.

### BRIEF DESCRIPTION OF THE DRAWINGS

FIG. 1A is a schematic cross-sectional view diagram illustrating integrated circuit devices including a photonic integrated circuit (PIC) die and a thermally conductive lid according to some embodiments of the present disclosure.

FIG. 1B is a schematic cross-sectional view diagram illustrating integrated circuit devices including an active bridge integrated circuit die and a thermally conductive lid according to some embodiments of the present disclosure.

FIG. 1C is a schematic cross-sectional view diagram illustrating integrated circuit devices including an application-specific integrated circuit (ASIC) die with a backside power delivery network (BSPDN) and a thermally conductive lid according to some embodiments of the present disclosure.

FIG. 1D is a schematic cross-sectional view diagram illustrating integrated circuit devices including a die stack with an ASIC die, a memory die, and a thermally conductive lid according to some embodiments of the present disclosure.

FIG. 1E is a schematic cross-sectional view diagram illustrating integrated circuit devices including a die stack with an ASIC die, an input/output (IO) die, and a thermally conductive lid according to some embodiments of the present disclosure.

FIG. 2A is a schematic plan view diagram illustrating an integrated circuit device package including integrated circuit devices having thermally conductive lids on ASIC dies attached on and/or embedded in a package substrate according to some embodiments of the present disclosure.

FIG. 2B is a schematic cross-sectional view diagram illustrating an integrated circuit device package including integrated circuit devices having thermally conductive lids on ASIC dies attached on and/or embedded in a package substrate according to some embodiments of the present disclosure, taken along line 2B-2B of FIG. 2A.

FIG. 2C is a schematic cross-sectional view diagram illustrating an integrated circuit device package including integrated circuit devices having thermally conductive lids on ASIC/memory/IO die stacks attached on and/or embedded in a package substrate according to some embodiments of the present disclosure.

FIG. 3A is a schematic plan view diagram illustrating an integrated circuit device package including integrated circuit devices having thermally conductive lids on PIC dies attached on and/or embedded in a package substrate according to some embodiments of the present disclosure.

FIG. 3B is a schematic cross-sectional view diagram illustrating an integrated circuit device package including integrated circuit devices having thermally conductive lids on PIC dies attached on and/or embedded in a package substrate according to some embodiments of the present disclosure, taken along line 3B-3B of FIG. 3A.

FIG. 4 is a schematic cross-sectional view diagram illustrating an integrated circuit device package including integrated circuit devices having thermally conductive lids on semiconductor dies attached on and/or embedded in an organic package substrate according to some embodiments of the present disclosure.

FIG. 5 is a schematic cross-sectional view diagram illustrating an integrated circuit device package including integrated circuit devices having thermally conductive lids on semiconductor dies embedded in and/or attached on opposite (top and bottom) sides of a package substrate according to some embodiments of the present disclosure.

FIGS. 6A1, 6A2, and 6A3 are schematic cross-sectional view diagrams illustrating methods of fabricating a thermally conductive lid layer according to some embodiments of the present disclosure.

FIGS. 6B1 and 6B2 are schematic cross-sectional view diagrams illustrating bonding and thinning a semiconductor wafer according to some embodiments of the present disclosure.

FIG. 6C is a schematic cross-sectional view diagram illustrating wafer-on-wafer bonding of the thermally conductive lid layer to the semiconductor wafer according to some embodiments of the present disclosure.

FIG. 6D is a schematic cross-sectional view diagram illustrating singulation of integrated circuit devices including semiconductor dies and thermally conductive lids according to some embodiments of the present disclosure.

FIGS. 7A1, 7A2, 7A3, 7A4, and 7A5 are schematic cross-sectional view diagrams illustrating methods of fabricating thermally conductive lids according to some embodiments of the present disclosure

FIGS. 7B1 and 7B2 are schematic cross-sectional view diagrams illustrating bonding and thinning a semiconductor wafer according to some embodiments of the present disclosure.

FIG. 7C is a schematic cross-sectional view diagram illustrating die-on-wafer bonding of the thermally conductive lids to the semiconductor wafer according to some embodiments of the present disclosure.

FIG. 7D is a schematic cross-sectional view diagram illustrating singulation of integrated circuit devices including semiconductor dies and thermally conductive lids according to some embodiments of the present disclosure.

FIG. 8A is a schematic cross-sectional view diagram illustrating methods of fabricating a (e.g., glass or silicon) package substrate at panel or wafer scale with thermal vias and liquid cooling channels according to some embodiments of the present disclosure.

FIG. 8B is a schematic cross-sectional view diagram illustrating methods of forming cavities in a package substrate according to some embodiments of the present disclosure.

FIG. 8C is a schematic cross-sectional view diagram illustrating methods of forming die backside films in cavities in a package substrate according to some embodiments of the present disclosure.

FIG. 8D is a schematic cross-sectional view diagram illustrating methods of embedding integrated circuit devices including thermally conductive lids in cavities in a package substrate according to some embodiments of the present disclosure.

FIG. 8E is a schematic cross-sectional view diagram illustrating methods of film lamination for redistribution layers according to some embodiments of the present disclosure.

FIG. 8F is a schematic cross-sectional view diagram illustrating methods of forming conductive lines, vias, and bumps in or on the redistribution layers according to some embodiments of the present disclosure.

FIG. 8G is a schematic cross-sectional view diagram illustrating methods of attaching integrated circuit devices to a surface of the package substrate at wafer or panel level according to some embodiments of the present disclosure.

FIG. 8H is a schematic cross-sectional view diagram illustrating methods of singulating the package substrate panel or wafer into respective integrated circuit device packages according to some embodiments of the present disclosure.

FIG. 8I is a schematic cross-sectional view diagram illustrating methods of attaching a thermal interface material (TIM) and/or thermally conductive lid or heat sink to an integrated circuit device package according to some embodiments of the present disclosure.

FIG. 9A is a schematic cross-sectional view diagram illustrating methods of fabricating a (e.g., glass or silicon) package substrate at panel or wafer scale with thermal vias and liquid cooling channels according to some embodiments of the present disclosure.

FIG. 9B is a schematic cross-sectional view diagram illustrating methods of forming cavities in a package substrate according to some embodiments of the present disclosure.

FIG. 9C is a schematic cross-sectional view diagram illustrating methods of forming die backside films in cavities in a package substrate according to some embodiments of the present disclosure.

FIG. 9D is a schematic cross-sectional view diagram illustrating methods of embedding integrated circuit devices including thermally conductive lids in cavities in a package substrate according to some embodiments of the present disclosure.

FIG. 9E is a schematic cross-sectional view diagram illustrating methods of film lamination for redistribution layers according to some embodiments of the present disclosure.

FIG. 9F is a schematic cross-sectional view diagram illustrating methods of forming conductive lines, vias, and bumps in or on the redistribution layers according to some embodiments of the present disclosure.

FIG. 9G is a schematic cross-sectional view diagram illustrating methods of attaching integrated circuit devices to a surface of the package substrate at wafer or panel level according to some embodiments of the present disclosure.

FIG. 9H is a schematic cross-sectional view diagram illustrating methods of attaching and optically coupling a fiber optic array unit to the embedded integrated circuit devices including thermally conductive lids in cavities in a package substrate according to some embodiments of the present disclosure.

### DETAILED DESCRIPTION OF EMBODIMENTS

Example embodiments are described herein with reference to the accompanying drawings, which may include cross-section illustrations that are schematic illustrations of idealized embodiments (and intermediate structures). The sizes and relative sizes of layers and regions may be exaggerated for clarity. Additionally, variations from the shapes of the illustrations as a result, for example, of manufacturing techniques and/or tolerances, are to be expected. The same reference numerals may be used to refer to the same or similar elements in various embodiments, where reference numerals followed by a dash (-1, -2, etc.) or one or more prime symbols (‘) can include specific instances or variations of the same or similar elements.

Advanced packages configurations may be desired to keep up with industry trends and to meet customer requirements, such as (but not limited to) providing high number of input/output (I/O), high bandwidth, low latency, high power efficiency, and/or small form factor (footprint). To meet these demands, heterogeneous integration and system-in-package (SiP) approaches have been proposed, including the use of interposers, redistribution layers (RDL), and advanced substrate technologies.

Heterogeneous integration, which may utilize die-to-die (D2D) interconnection, and 2.5D and 3D die embedding and stacking to assemble multiple (e.g., best available) chip technologies with different functions, types, and sizes (including smaller semiconductor chips, also referred to as chiplets) into the same compact package or assembly, is an advanced packaging technology being developed. To meet high-performance computing (HPC) and artificial intelligence (AI) market demands of higher performance, lower power consumption, and wider memory bandwidth with reduced latency, smaller interconnects may be used for connecting D2D in advanced packages with a tighter bump pitch. While the interconnects may be smaller and denser, the overall package size may be increasing, as more chiplets and high bandwidth memory (HBM) may be assembled on a same package to meet high performance requirements. Such larger and denser packages may present thermal management challenges.

Glass and/or silicon (Si) substrates may be used to accommodate heterogeneous integration in advanced packaging technologies. Such substrates may have improved mechanical properties compared with organic substrates, and may be used to fabricate larger packages. Backside power delivery network (BSPDN) structures in a silicon architecture may also be applied to a 2 nanometer (nm) or smaller silicon (Si) nodes to improve power delivery performance to an ASIC or other electronic integrated circuit (EIC) chip, with reduced routing congestion in a back end of line (BEOL) structure, by separating the power delivery network (PDN) from the signal layers. BSPDN structures may improve, for example, power rail effectiveness, voltage drop (i.e., IR drop), high power delivery performance, and scaling of standard cell height.

Co-packaged optics (CPO), also known as integrated photonics, is a technology that aims to integrate optical components, such as lasers, modulators, and waveguides, into a single package with electronic chips. This integration may enable high-speed data transmission and processing with reduced power consumption and improved efficiency. CPOs can reduce or minimize the power of electrical links to or from the optics and may require higher data transmission speed, which can be achieved through 2.5D or 3D advanced packaging with much denser and smaller interconnects.

Embedding chiplets and bridge dies in glass or Si substrates may produce large 2.5D or 3D packages with dense D2D interconnects. For CPO packaging applications, embedding photonic integrated circuit (PIC) chips in glass, Si, or organic substrates can help improve performance with a lower cost. However, better thermal management may be needed to help quickly spread localized high-temperature regions (also referred to herein as hot spots) in the active dies. In particular, embedded PIC and/or EIC chiplets with BSPDN in glass or Si substrates may pose significant challenges for thermal management.

Some embodiments of the present disclosure may arise from realization that the thermal conductivity of diamond (e.g., about 2000 to about 3300 Watts per meter-Kelvin (W/mK)) may be about 10-20 times higher than the thermal conductivity of Si (e.g., about 130 to about 150 W/mK), and about 5-7 times higher than the thermal conductivity of copper (Cu) (e.g., about 400 W/mK). Diamond (or other wide-bandgap semiconductor or insulator materials) may thus be a promising material for better thermal management in 3D ICs, by efficiently spreading hot spots generated by active dies. Single crystal diamond (SCD) wafers with variable thickness (e.g., about 2 µm to about 400 µm, for example, about 2 µm to about 100 µm or about 2 µm to about 50 µm) may be bonded to the backside of a graphics processing unit (GPU) or other semiconductor die as a thermally conductive lid, for improved thermal management. The minimum thickness of the SCD (or other layer) of the thermally conductive lid can be selected to achieve the thermal performance or chip/package size requirements (and associated thermal requirements). Other wide-bandgap materials (such as polycrystalline diamond, aluminum nitride (AlN), boron nitride (BN), gallium nitride (GaN), and/or silicon carbide (SiC)) may alternatively be used to implement a thermally conductive lid to provide similar thermal performance.

Some embodiments of the present disclosure provide integrated circuit devices and packages that include diamond (or other wide-bandgap semiconductor or insulator material) to help with thermal management. For example, an electronic or photonic integrated circuit chip or chiplet may be bonded to a diamond (or other wide-bandgap semiconductor or insulator material) layer as a thermally conductive lid that is external to the chip or chiplet, to provide improved heat dissipation. In some embodiments, the thermally conductive lid may include one or more additional layers, to reduce the thickness (and associated cost) of the diamond (or other wide-bandgap semiconductor or insulator material) layer. The additional layer(s) may include the same semiconductor material as the chips or chiplets, for process compatibility.

In particular, embodiments of the present disclosure provide packaging architectures (including integrated circuit devices, packages, and fabrication methods) including a package substrate (such as a glass and/or silicon substrate) with active semiconductor dies (including EIC and/or PIC chips or chiplets) having thermally conductive lid members or structures (also referred to as thermally conductive lids) bonded thereon. For example, an EIC or PIC chip or chiplet may be bonded to a diamond (or other wide-bandgap semiconductor or insulator material) layer as a thermally conductive lid, and may be embedded in a package substrate (such as a glass or Si substrate) or attached to a surface of the package substrate. The thermally conductive lids may include one or more layers of wide-bandgap insulator or semiconductor materials (such as diamond, Group-III nitrides, or SiC) bonded to surfaces of the EICs and/or PICs. As used herein, a wide-bandgap material can include a semiconductor or insulator material having an energy bandgap greater than that of silicon, for example, greater than about 2 electron-Volts (eV).

The thermally conductive lid may not include (i.e., may be free of) electrical connections (such as through diamond vias) therein, and may provide improved heat dissipation. In some embodiments, the thermally conductive lid may include one or more additional layers, to reduce the thickness (and associated cost) of the diamond (or other wide-bandgap semiconductor or insulator material) layer. The additional layer(s) may include the same semiconductor material as the chips or chiplets (more generally referred to herein as semiconductor dies). For example, the semiconductor dies may be silicon, silicon germanium, silicon carbide, and/or Group III nitride (e.g., including indium, gallium, and/or aluminum nitride) devices, and the thermally conductive lids may further include a layer of the same material as the semiconductor dies on the wide-bandgap layers, for process compatibility.

Packaging architectures as described herein may provide improved thermal management of hot spots generated by the active EIC or PIC chiplets, and may significantly improve device performance. In some embodiments, the EICs may include a BSPDN, where a backside of a substrate is used as a power delivery network. In a BSPDN structure, backside power rails may be formed on the backside of the device, rather than on the frontside thereof. For example, the BSPDN may be provided in or on one or more bottom layers of a transistor structure to further improve the integration degree, power level, and performance of an integrated circuit device. As such, the backside power rails may be on a side of the substrate that is opposite from the active components (e.g., transistors). The BSPDN may further include a backside insulator with conductive via plug(s) and/or conductive wire(s) therein that electrically connect to one or more of the backside power rails to facilitate power delivery. The backside insulator may include, for example, one or more layers including insulating material(s) (e.g., silicon oxide, silicon oxynitride, silicon nitride, silicon carbonitride, silicon boron carbonitride, and/or a low-k material). In some EICs, upper structures including conductive elements for data signals may be on the frontside of the device, and thus the BSPDN structure and the conductive elements for the data signals may be on opposite sides of the substrate. The frontside conductive elements and/or the backside power rails may include metal layers or materials including, for example, tungsten (W), aluminum (Al), copper (Cu), molybdenum (Mo), cobalt (Co) and/or ruthenium (Ru).

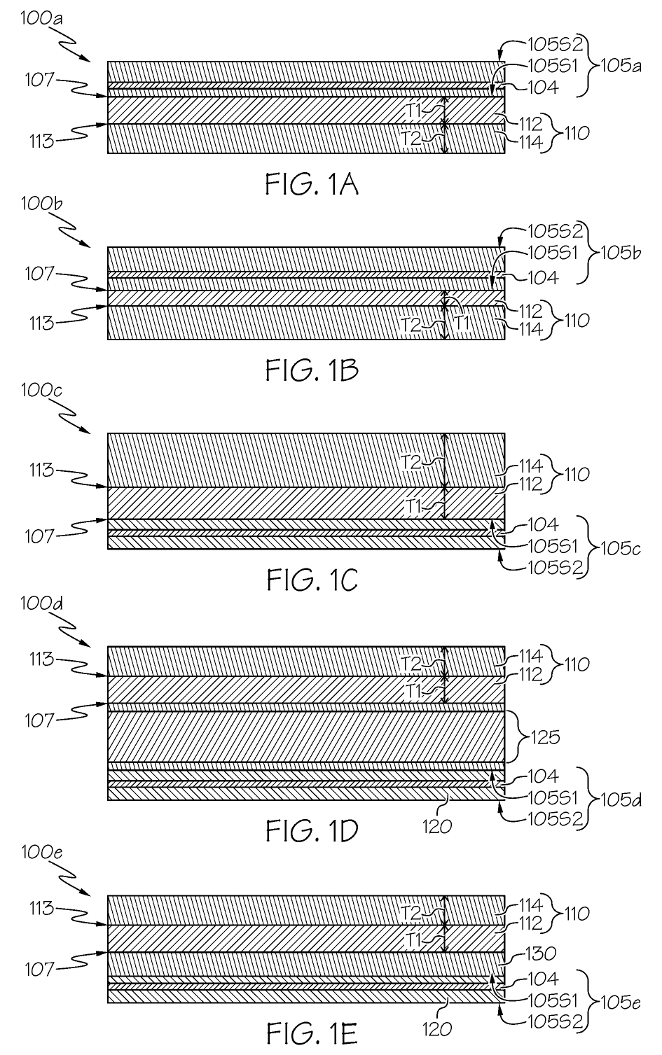

FIGS. 1A, 1B, 1C, 1D, and 1E are schematic cross-sectional view diagrams illustrating integrated circuit devices 100a, 100b, 100c, 100d, and 100e (collectively, 100) including various semiconductor dies 105a, 105b, 105c, 105d, and 105e (collectively, 105) and thermally conductive lids according to some embodiments of the present disclosure. The various semiconductor dies 105 include EICs and/or PICs. For example, the semiconductor dies 105 may include a PIC die 105a (in FIG. 1A), an active bridge integrated circuit die 105b (in FIG. 1B), an application-specific integrated circuit (ASIC) die 105c with a BSPDN 120 (in FIG. 1C), a die stack with an ASIC die 105d and a memory die 125 (such as a high bandwidth memory chip stack) (in FIG. 1D), and a die stack with an ASIC die 105e and an input/output (IO) die 130 (in FIG. 1E).

As shown in FIGS. 1A-1E, integrated circuit devices 100a-100e include a semiconductor die 105 having an active layer 104 between a first surface 105S1 and second surface 105S2, and a thermally conductive lid 110 that is bonded or otherwise attached to the first surface 105S1 of the semiconductor die 105. The thermally conductive lid 110 may have a single layer or multi-layer structure that includes one or more wide-bandgap material layers, such as (but not limited to) diamond (including single crystal and polycrystalline diamond), aluminum nitride, boron nitride, gallium nitride, or silicon carbide. The wide-bandgap material layer(s) are thermally conductive (e.g., with a thermal conductivity of greater than about 200 W/mK). The wide-bandgap material layer(s) may be electrically insulating (e.g., with an electrical conductivity of less than about 1 x 10⁻¹⁰ Siemens per meter (S/m)) in some embodiments, or may be electrically conductive (e.g., with an electrical conductivity of greater than about 1 x 10⁵ S/m) in some embodiments. The thermally conductive lid 110 is distinct from (i.e., external to) the layers of the semiconductor die 105, and is free of electrical connections (e.g., conductive traces and/or vias) therein.

In particular, in the examples of FIGS. 1A-1E, the thermally conductive lid 110 may include a first layer 112 of a first material on the first surface 105S1 of the semiconductor die 105 and a second layer 114 of a second material on the first layer 112 opposite the first surface 105S1, where the first material has a wider bandgap than the second material. For example, as noted above, the first material of the first layer 112 may be a wide-bandgap material that is thermally conductive (and may or may not be electrically insulating). The second material of the second layer 114 may be a semiconductor material, such as (but not limited to) silicon, gallium nitride, silicon carbide, or glass. The second material of the second layer 114 may be the same material as semiconductor die 105 (or the active layer 104), for example, for compatibility with one or more common fabrication processes. That is, both the second layer 114 and the semiconductor die 105 may include the same semiconductor material in some embodiments.

The wide-bandgap material first layer 112 is bonded to the first surface 105S1 of the semiconductor die 105 with a first bonding interface 107 therebetween, and the semiconductor material second layer 114 is bonded to a surface of the wide-bandgap material first layer 112 with a second bonding interface 113 therebetween. In some embodiments, the active layer 104 of the semiconductor die 105 may be closer to the first surface 105S1 (or bonding interface 107 with the first layer 112 of the thermally conductive lid 110) than the second surface 105S2, for improved heat dissipation. In other words, a surface of the active layer 104 is a first distance from the first surface 105S1 and is a second distance from the second surface105S2, where the first distance is smaller than the second distance. While not shown to scale, in some embodiments, the first layer 112 may have a first thickness T1 that is thinner (e.g., at least five times thinner) than a second thickness T2 of the second layer 114. For example, the thickness T1 of the first layer 112 may be about 2 µm to about 100 µm (e.g., about 2 µm to about 50 µm), and the thickness T2 of the second layer 114 may be about 50 µm to about 700 µm.

According to some example embodiments of the present disclosure, the first material of the first layer 112 of the thermally conductive lid 110 may be single-crystal diamond (SCD), and the second material of the second layer 114 of the thermally conductive lid 110 may be silicon. In particular, the first layer 112 may be or may include a SCD or other diamond layer as a thermal solution for quickly spreading hot spots in an active semiconductor die 105. For example, the second layer 114 may be a thin Si layer that is bonded to the backside or back surface of the thin SCD first layer 112 to form a thermally conductive lid 110 (also referred to herein as a Si-SCD lid or SCD-Si lid), e.g., by utilizing die embedding and die stacking techniques. The frontside or front surface of the thin SCD first layer 112 may be bonded to a front or first surface 105S1 of the semiconductor die 105 (which may be a PIC or an EIC with or without a BSPDN). The thickness T1 of the first layer 112 and the thickness T2 of the second layer 114 may be adjusted to fulfill package (e.g., semiconductor package) configuration requirements, e.g., based on thermal performance and chip size. For example, the second layer 114 may be a “dummy” Si layer (or other semiconductor layer that is free of electrical connections therein) that is bonded to the backside of the SCD layer 112 (which is likewise free of electrical connections or elements, such as through-diamond vias (TDVs)). Providing the second layer 114 as an additional layer of the thermally conductive lid 110 can reduce costs (e.g., by allowing for a thinner SCD layer 112) without sacrificing thermal performance. Also, using the same material (e.g., Si) for both the second layer 114 and the semiconductor die 105 may allow leveraging of common die embedding and die stacking processes. However, it will be understood that the thermally conductive lid 110 may not include the second layer 114 in some embodiments.

As shown in the example of FIG. 1A, the semiconductor die 105a may be a PIC chip or chiplet, and the thermally conductive lid 110 (in particular, the wide-bandgap first layer 112 thereof) may be bonded to a first surface 105S1 of the PIC chip or chiplet. As shown in the example of FIG. 1B, the semiconductor die 105b may be a EIC chip or chiplet (e.g., an active bridge chip or chiplet), and the thermally conductive lid 110 (in particular, the wide-bandgap first layer 112 thereof) may be bonded to a first surface 105S1 of the EIC chip or chiplet.

In some embodiments, the active layer 104 may be closer to the first surface 105S1 than to the opposing second surface 105S2. That is, a surface of the active layer 104 is a first distance from the first surface 105S1 and is a second distance from the second surface105S2, where the first distance is smaller than the second distance. As such, the first layer 112 (e.g., an SCD layer) may be bonded very close to the transistor devices of the active layer 104 (where charge carrier interaction occurs), which may help quickly spread or dissipate local hot spots generated by the active integrated circuits in the semiconductor dies 105a, 105b, thereby improving thermal management as well as performance of the integrated circuit devices 100a, 100b.

As shown in the example of FIG. 1C, the semiconductor die 105c may be an ASIC including an active layer 104 and a backside power delivery network (BSPDN) 120. The thermally conductive lid 110 (in particular, the wide-bandgap first layer 112) may be bonded to a first surface 105S1 of the semiconductor die 105c adjacent to the active layer 104. The BSPDN 120 may be adjacent to the second surface 105S2 of the semiconductor die 105c, that is, opposite the thermally conductive lid 110.

As shown in the example of FIG. 1D, a memory die 125 (e.g., a high capacity memory chip stack, such as high bandwidth memory (HBM)) may be provided between the ASIC or other semiconductor die 105d and the thermally conductive lid 110. The memory die 125 may be bonded to a first surface 105S1 of the semiconductor die 105d adjacent to the active layer 104 (e.g., for ease of interconnection between the ASIC and the stacked memory chips), and the thermally conductive lid 110 (in particular, the wide-bandgap first layer 112) may be bonded to a surface of the memory die 125 opposite the semiconductor die 105d.

Similarly, as shown in the example of FIG. 1E, an input/output (IO) die 130 (e.g., a memory IO die) may be provided between the ASIC or other semiconductor die 105e and the thermally conductive lid 110. The IO die 130 may be bonded to a first surface 105S1 of the semiconductor die 105e adjacent to the active layer 104, and the thermally conductive lid 110 (in particular, the wide-bandgap first layer 112) may be bonded to a surface of the IO die 130 opposite the semiconductor die 105e.

For example, a thermally conductive lid 110 including a first layer 112 of SCD and a second layer 114 of Si can be bonded to an ASIC 105c with a BSPDN 120, an ASIC/HBM die stack 105d/125, or an ASIC/IO die stack 105e/130. In particular, as shown in FIGS. 1D and 1E, an ASIC die 105d or 105e may be bonded to a memory die 125 (such as a HBM) or to an IO die 130 at a first surface 105S1 thereof, e.g., using hybrid bonding techniques. Each ASIC die 105d or 105e includes a BSPDN 120 adjacent to a second surface 105S2 thereof. The thermally conductive lid 110 (more particularly, the first layer 112) may be bonded to a surface of the memory die 125 or the IO die 130 opposite the ASIC die 105d or 105e. This arrangement can provide memory integration solutions for microelectronic devices with wider bandwidth, faster speed, and larger capacity, while addressing hot spot issues.

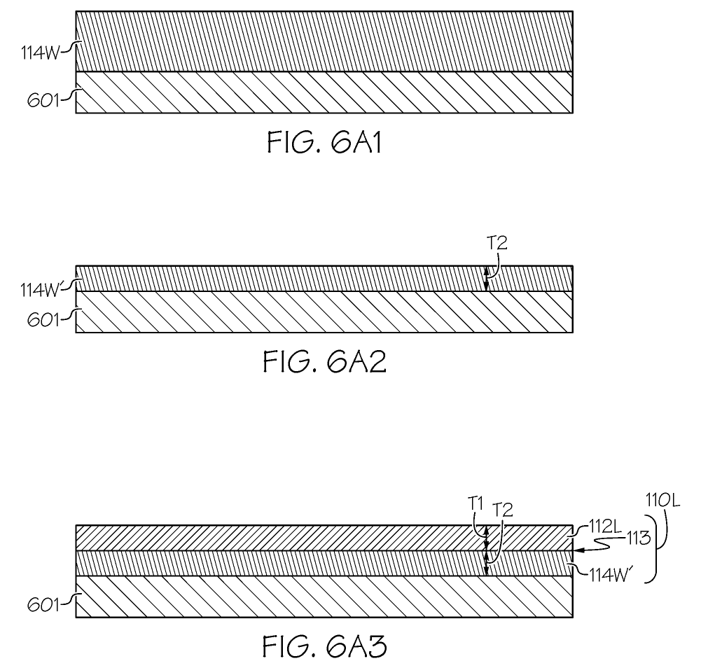

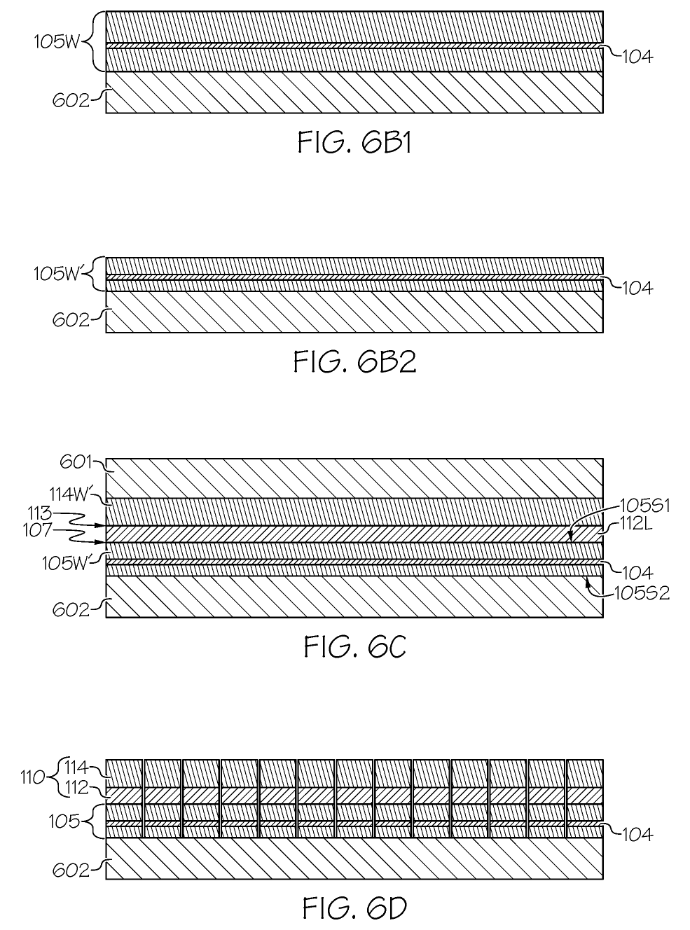

As described in greater detail below with reference to FIGS. 6A1-6D and 7A1-7D, the first bonding interface 107 with the first (diamond or other wide-bandgap material) layer 112 may be a die-on-wafer (DoW) bonding interface or a wafer-on-wafer (WoW) bonding interface. In some embodiments, the second bonding interface 113 between the first layer 112 and the second (semiconductor material) layer 114 may be a wafer-on-wafer bonding interface.

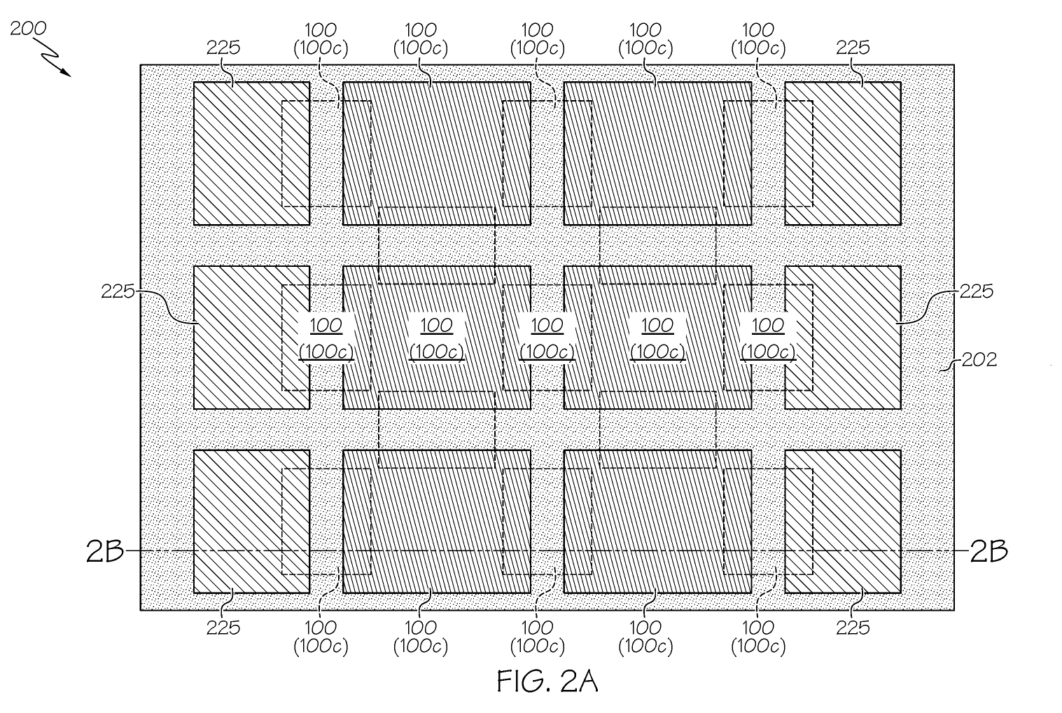

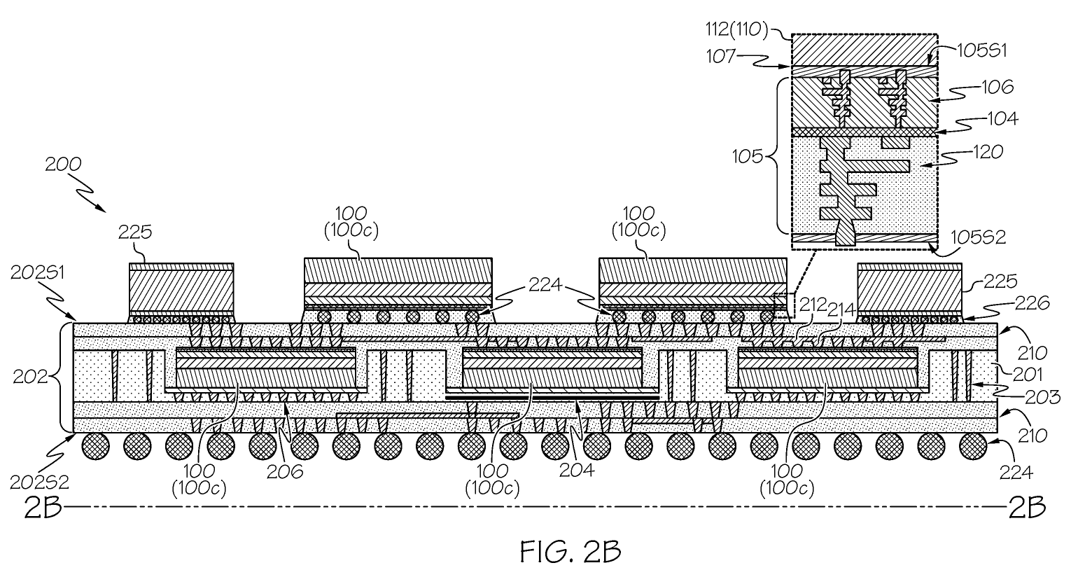

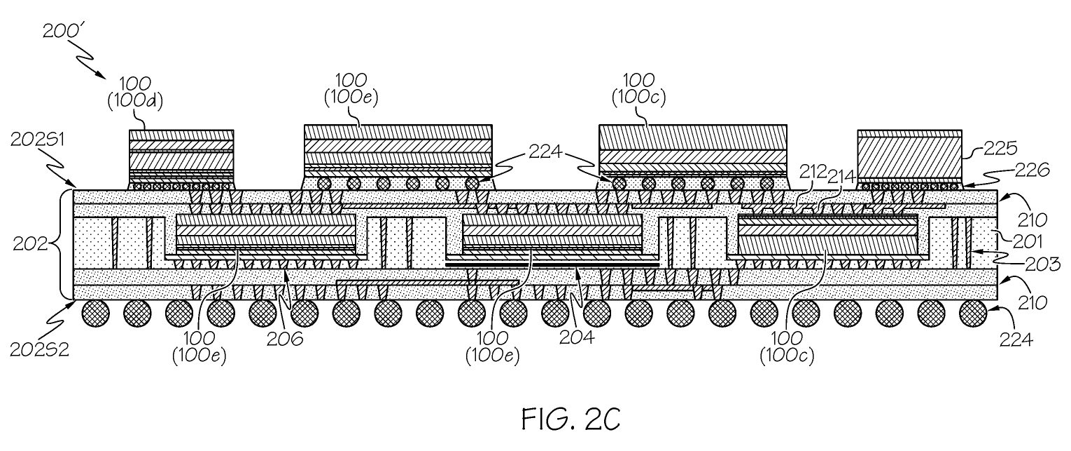

Also, as described in greater detail below with reference to FIGS. 2A-5, the PIC device 100a or EIC devices 100b-100eincluding thermally conductive lids 110 as described herein may be provided on one or more surfaces of a package substrate (e.g., an organic, glass, or semiconductor substrate). For example, one or more of the integrated circuit devices 100a-100e may be embedded in a package substrate to provide active bridge dies connected by a redistribution layer (RDL), using panel or wafer level packaging processes. Any of such integrated circuit devices 100a-100e (which may be chips or smaller chiplets) can also be assembled on top (i.e., attached to one or more surfaces) of a package substrate having embedded active bridge dies or chiplets therein to provide 2.5D or 3D packages.

That is, PIC and/or EIC (including BSPDN) chiplets having thermally conductive lids as described herein may be used in advanced packaging architectures that integrate memory and/or active bridge dies at a wafer or panel level, for various different substrates (e.g., organic, Si, or glass substrates). In particular, the use of glass and Si substrates can allow larger package sizes as compared with packages including organic substrates. For example, better electrical performance can be achieved due to superior thermal and/or insulating material properties of glass. Additionally, liquid cooling channels or thermal vias can be included in the glass and Si substrates to further improve the thermal performance, and integrated stacked capacitors (ISC) can be embedded in the glass and Si substrates to further improve the power delivery network (PDN) performance.

While illustrated in FIGS. 1A-1E with reference to specific examples of semiconductor dies 105 including thermally conductive lids 110 thereon, it will be understood that these examples are non-exhaustive. Thermally conductive lids 110 as described herein may similarly be attached, for example, to a central processing unit (CPU), GPU, AI chips, SoC, system-in-package (SIP), etc.

FIG. 2A is a schematic plan view diagram illustrating an integrated circuit device package including integrated circuit devices having thermally conductive lids on ASIC dies (including BSPDNs) that are attached on and/or embedded in a package substrate according to some embodiments of the present disclosure. FIG. 2B is a schematic cross-sectional view diagram taken along line 2B-2B of FIG. 2A.

As shown in FIGS. 2A and 2B, an integrated circuit device package 200 includes a package substrate 202 and integrated circuit devices 100 (shown by way of example as the integrated circuit devices 100c of FIG. 1C) adjacent to a top or upper surface 202S1 of the package substrate 202. The integrated circuit devices 100 each include a semiconductor die 105 (having an active layer 104 between opposing first and second surfaces 105S1 and 105S2, signal layers 106 adjacent to the first surface 105S1, and a BSPDN 120 adjacent to the second surface 105S2; see inset image) with a thermally conductive lid 110. The semiconductor die 105 is between the thermally conductive lid 110 and the top or upper surface 202S1 of the package substrate 202. In particular, the second surface 105S2 of the semiconductor die 105 is attached to the top surface 202S1 of the package substrate 202 (with the BSPDN 120 facing the top surface 202S1), and the first surface 105S1 of the semiconductor die 105 (having the thermally conductive lid 110 thereon) is opposite the top surface 202S1 of the package substrate 202.

As described in detail above with reference to FIGS. 1A-1E, the thermally conductive lid 110 includes a first layer 112 of a first material on the first surface 105S1 of the semiconductor die 105 and a second layer 114 of a second material on the first layer 112 opposite the first surface 105S1, where the first material has a wider bandgap than the second material. In some embodiments, the first material is a wide-bandgap material (e.g., diamond, such as SCD), and the second material is a semiconductor material (e.g., silicon). The semiconductor die 105 (or the active layer 104 thereof) may also include the same second material as the second layer 114 of the thermally conductive lid 110, e.g., for reduced cost (as the wide-bandgap material first layer 112 can be made thinner) and increased process compatibility (with the fabrication processes associated with forming the semiconductor die 105).

In the examples of FIGS. 2A and 2B, some of the integrated circuit devices 100c (along with additional components, shown as memory dies 225) are attached to the surface 202S1 of the package substrate 202 (e.g., by conductive joints 224 (such as solder balls or conductive pillars) with underfill layers 226 therebetween), while others of the integrated circuit devices 100c are embedded in the package substrate 202 below the surface 202S1thereof. In particular, the package substrate 202 includes a core layer 201 (with one or more through vias 203 therein) and redistribution layers 210 thereon between the top surface 202S1and the bottom surface 202S2. The core layer 201 may include one or more glass, semiconductor, and/or organic layers in some embodiments. The through vias 203 may be conductive vias that extend through the core layer 201 (e.g., through glass vias or through silicon vias) to provide electrical connections between the redistribution layers 210 adjacent to the top surface 202S1 and the bottom surface 202S2.

The redistribution layers 210 adjacent to the top surface 202S1 extend on the second surface 105S2 of the semiconductor die 105 of the respective integrated circuit devices 100c. The redistribution layers 210 include conductive lines 212 and conductive vias 214 electrically connected to the BSPDN 120 and/or active layer 104 of the semiconductor dies 105. The embedded integrated circuit devices 100c thus provide active bridge components that can electrically connect components (shown as integrated circuit devices 100c and 225) that are attached to the surface 202S1 of the package substrate 202. In some embodiments, the core layer 201 of the package substrate 202 may further include liquid cooling channels 204 and/or thermally conductive vias 206 extending under or adjacent to the thermally conductive lids 110 of the embedded integrated circuit devices 100c. The liquid cooling channels 204 and thermally conductive vias 206 may be positioned along surfaces of the thermally conductive lids 110 so as to further distribute heat and/or reduce hot spots in the package substrate 202. More particularly, the liquid cooling channels 204 are configured to circulate a liquid coolant therein, while the thermally conductive vias 206 are configured to conduct heat away from the semiconductor dies 105.

While shown in FIGS. 2A and 2B with the integrated circuit devices 100c of FIG. 1C (having thermally conductive lids 110 bonded to ASIC dies 105c including BSPDNs 120) in or on the package substrate 202, it will be understood that integrated circuit device packages 200 as described herein are not limited to the illustrated embodiments. For example, FIG. 2C is a schematic cross-sectional view diagram illustrating an integrated circuit device package 200’ that is similar to the integrated circuit device package 200 of FIG. 2B (with like elements labeled with like reference numbers), but further includes one or more integrated circuit devices 100d of FIG. 1D (with thermally conductive lids 110 on ASIC/memory die stacks 105d/125) attached to the top surface 202S1 of the package substrate 202 by conductive joints 224 with underfill layers 226 therebetween.

More generally, although illustrated in FIGS. 2A-2C with reference to specific examples of integrated circuit devices 100 embedded in a package substrate 202 or attached to a top surface 202S1 of the package substrate 202, it will be understood that any of the components 100a-100e described above with reference to FIGS. 1A-1E may be used interchangeably with the illustrated integrated circuit devices 100 in the packages 200, 200’. That is, as illustrated in FIGS. 2A-2C, the thermally conductive (e.g., SCD-Si) lids 110 may be bonded on various semiconductor dies 105 that are embedded into or attached onto the top of (e.g., glass or Si) package substrates 202 to provide large 2.5D or 3D packages 200, 200’ with improved thermal performance. Also, embedded liquid cooling channels 204 and thermally conductive vias 206 can be provided inside the core layer 201 of the (e.g., glass or Si) package substrate 202, to further improve the thermal performance.

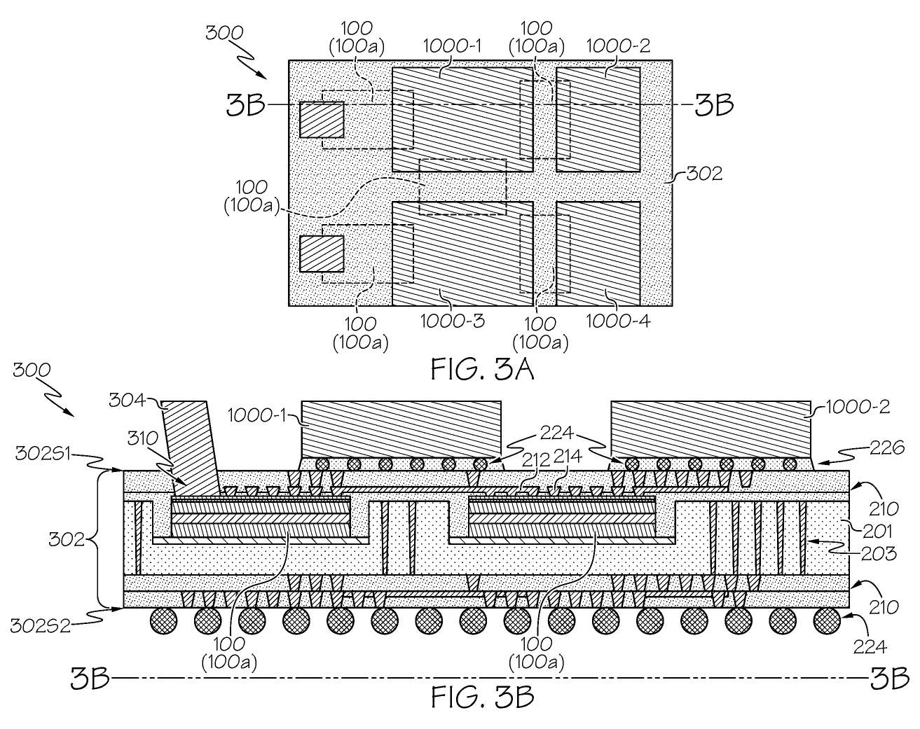

FIG. 3A is a schematic plan view diagram illustrating an integrated circuit device package including integrated circuit devices having thermally conductive lids on PIC dies attached on and/or embedded in a package substrate according to some embodiments of the present disclosure. FIG. 3B is a schematic cross-sectional view diagram taken along line 3B-3B of FIG. 3A.

As shown in FIGS. 3A and 3B, an integrated circuit device package 300 includes a package substrate 302 with components 1000-1, 1000-2, 1000-3, 1000-4 attached to a top surface 302S1 (e.g., by conductive joints 224 with underfill layers 226 therebetween), and one or more integrated circuit devices 100 (shown by way of example as the PIC devices 100a of FIG. 1A) embedded in the package substrate 302 below the top surface 302S1. The integrated circuit devices 100a each include a PIC die 105a (having an active layer 104 between opposing first and second surfaces 105S1 and 105S2) and a thermally conductive lid 110 (see FIG. 1A) on the first surface 105S1. The thermally conductive lid 110 includes a first layer 112 of a first, wide-bandgap material (e.g., diamond, such as SCD), and a second layer 114 of a second material (e.g., semiconductor, such as silicon, gallium nitride, or silicon carbide). The PIC die 105a (or the active layer 104 thereof) may also include the same second material as the second layer 114 of the thermally conductive lid 110 in some embodiments.

The integrated circuit devices 100a are embedded in the package substrate 302 such that the PIC die 105a is between the thermally conductive lid 110 and the top surface 302S1 of the package substrate 302. In particular, the second surface 105S2 of the PIC die 105a adjacent to the top surface 302S1 of the package substrate 302, and the first surface 105S1 of the PIC die 105a (having the thermally conductive lid 110 thereon) is opposite the top surface 302S1 of the package substrate 302.

In the examples of FIGS. 3A and 3B, the integrated circuit device package 300 further includes a fiber optic array unit (FAU) 304 that is optically coupled to one of the PIC dies 105a at the second surface 105S2. More particularly, similar to the package substrate 202 of FIGS. 2A-2C, the package substrate 302 includes a core layer 201 (with one or more through vias 203 therein) and redistribution layers 210 thereon between the top surface 302S1 and the bottom surface 302S2. The redistribution layers 210 adjacent to the top surface 302S1 extend on the second surface 105S2 of the PIC die 105a of the respective integrated circuit devices 100a, and include conductive lines 212 and conductive vias 214 electrically connected to the PIC dies 105a. The redistribution layers 210 adjacent to the top surface 302S1 further include an opening 310 therein, and the FAU 304 extends through the opening 310 to contact the second surface 105S2 of one of the PIC die 105a.

At least one embedded integrated circuit device 100a thus provides an optical interface between the FAU 304 (which provides optical signals from an external device) and the component 1000-1 (or 1000-3) attached to the top surface 302S1 of the package substrate 302. One or more other embedded integrated circuit devices 100a may provide electrical and/or optical bridge components that can electrically connect the components 1000-1, 1000-2, 1000-3, and/or 1000-4 that are attached to the surface 302S1 of the package substrate 302. In some embodiments, the core layer 201 of the package substrate 302 may further include liquid cooling channels and/or thermally conductive vias extending under or adjacent to the thermally conductive lids 110 of the embedded integrated circuit devices 100a, to further distribute heat and/or reduce hot spots in the package substrate 302.

As illustrated in FIGS. 3A-3B, the thermally conductive (e.g., SCD-Si) lids (110 in FIG. A) are bonded on various PIC dies (105a in FIG. 1A) that are embedded into (e.g., glass or Si) package substrates 302 to provide advanced CPO packages with improved thermal performance. Also, while not specifically illustrated, it will be understood that the components 1000-1 to 1000-4 attached to the surface 302S1 of the package substrate 302 may (but do not necessarily) include respective thermally conductive lids 110 thereon, or may represent any of the components 100a-100e described above with reference to FIGS. 1A-1E.

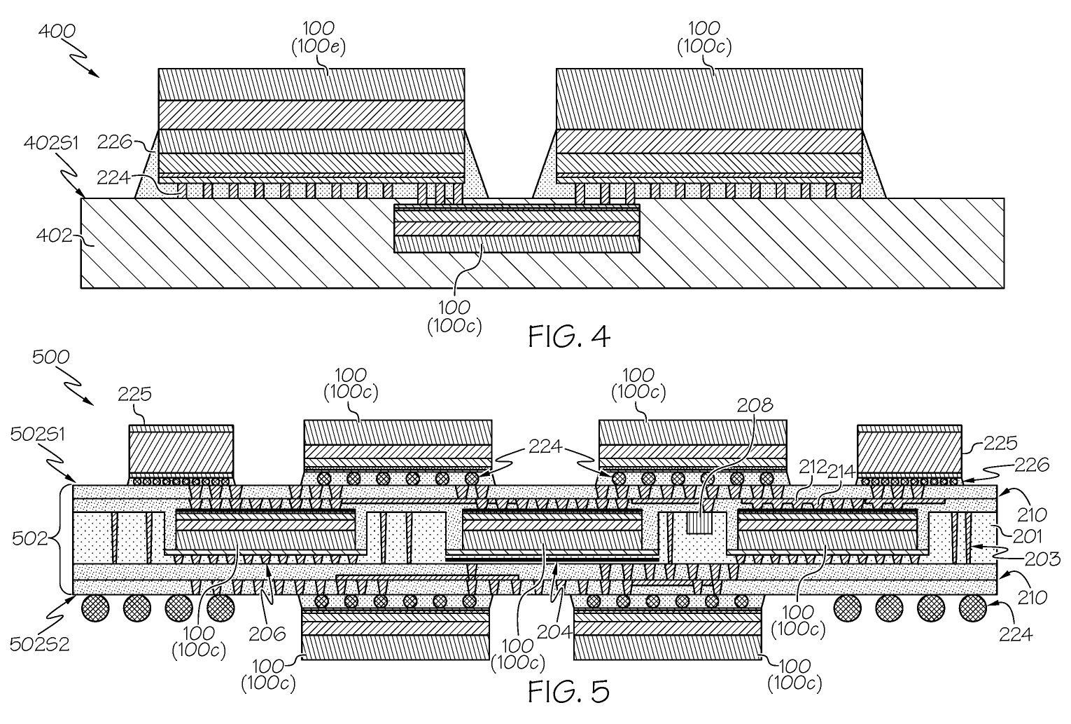

FIG. 4 is a schematic cross-sectional view diagram illustrating an integrated circuit device package including integrated circuit devices having thermally conductive lids on semiconductor dies attached on and/or embedded in an organic package substrate according to some embodiments of the present disclosure. As shown in FIG. 4, the integrated circuit device package 400 includes a package substrate 402 and integrated circuit devices 100 (shown by way of example as the integrated circuit devices 100c of FIG. 1C and 100e of FIG. 1E) attached to a top surface 402S1 of the package substrate 402 (e.g., by conductive joints 224 with underfill layers 226 therebetween). The integrated circuit device package 400 further includes one or more integrated circuit devices (shown by way of example as the integrated circuit device 100c of FIG. 1C) embedded in the package substrate 402 below the top surface 402S1. In contrast to the embodiments of FIGS. 2A-2C and 3A-3B, the package substrate 402 includes an organic material, rather than glass or semiconductor. The organic material of the package substrate 402 may include, for example, polyimide (PI), polyphenylene ether (PPE) resin, epoxy resin (FR4), or bismaleimide triazine (BT) resin.

FIG. 5 is a schematic cross-sectional view diagram illustrating an integrated circuit device package including integrated circuit devices having thermally conductive lids on semiconductor dies embedded in and/or attached on multiple surfaces (e.g., top and bottom) of a package substrate according to some embodiments of the present disclosure. As shown in FIG. 5, an integrated circuit device package 500 includes a package substrate 502 and integrated circuit devices 100 (shown by way of example as the integrated circuit devices 100c of FIG. 1C) adjacent to the top surface 502S1 and the bottom surface 502S2 of the package substrate 502. In particular, some of the integrated circuit devices 100c (along with additional components, shown as memory dies 225) are attached to the top surface 502S1 of the package substrate 502 (e.g., by conductive joints 224, with underfill layers 226 therebetween), while others of the integrated circuit devices 100c are embedded in the package substrate 502 below the top surface 502S1, and still others of the integrated circuit devices 100c are attached to the bottom surface 502S2 of the package substrate 502.

That is, the integrated circuit device package 500 of FIG. 5 may be similar to the integrated circuit device package 200 of FIG. 2B (with like elements labeled with like reference numbers), but further includes one or more integrated circuit devices 100c attached to the bottom surface 502S2 of the package substrate 502 by conductive joints 224 with underfill layers 226 therebetween. The integrated circuit device package 500 may further include an integrated stacked capacitor (ISC) 208 embedded in the package substrate 502 below the surface 502S1.

That is, FIGS. 4 and 5 illustrate alternatives packages 400 and 500, according to some example embodiments of the present disclosure, where the thermally conductive (e.g., SCD-Si) lids 110 are bonded on various semiconductor dies (including chiplets) that are embedded in or assembled on organic substrates, or on multiple (e.g., opposing) sides of glass or Si substrates. Although illustrated in FIGS. 4 and 5 with reference to specific examples of integrated circuit devices 100 embedded in a package substrate 402, 502 or attached to a top surface 402S1, 502S1 or a bottom surface 502S2 of the package substrate 402, 502, it will be understood that any of the components 100a-100edescribed above with reference to FIGS. 1A-1E may be used interchangeably with the illustrated integrated circuit devices 100.

As noted above, in particular embodiments, the integrated circuit devices 100 described herein may be implemented as EIC or PIC chiplets with diamond (e.g., SCD)-based thermally conductive lids bonded thereto, and may be embedded in glass or Si or organic substrates to provide advanced packaging solutions with improved heat dissipation and/or reduced hot spots. In some embodiments, the thermally conductive lids may further include a Si layer that is bonded to the backside of the SCD layer, and the SCD-Si lids may be bonded to the EIC or PIC chiplets to provide EIC/PIC-SCD-Si chiplets. Bonding an Si layer to the backside of an SCD layer can allow for reduced costs by reducing the thickness of the (more expensive) SCD layer without reducing performance. Additionally, bonding the Si layer to the backside of the SCD layer to provide a thermally conductive lid may provide compatibility with die embedding, stacking, and/or other fabrication processes developed for Si chiplets, due to the use of the same material (Si) in both the chiplets and the thermally conductive lids thereon.

Example fabrication processes for forming thermally conductive lids on semiconductor dies (e.g., SCD bonded chiplets) according to embodiments of the present disclosure are described in greater detail below. In particular, FIGS. 6A1, 6A2, 6A3, 6B1, 6B2, 6C, and 6D (collectively, FIG. 6) are schematic cross-sectional view diagrams illustrating methods of fabricating integrated circuit devices including semiconductor dies and thermally conductive lids using wafer-on-wafer (WoW) bonding according to some embodiments of the present disclosure. WoW bonding can include a semiconductor manufacturing process that involves joining two entire wafers together (either temporarily for support or permanently) to create integrated devices, without the use of traditional conductive bumps or solder. WoW bonding can be achieved through various methods, including direct fusion bonding (e.g., at high temperature and pressure), anodic bonding (e.g., using electric field and heat), adhesive bonding, or hybrid bonding (e.g., bonding dielectric surfaces and fusing copper-to-copper interconnects).

As shown in FIG. 6A1, a semiconductor wafer 114W is bonded to or otherwise provided on a carrier wafer 601. For example, the semiconductor wafer 114W may be a silicon, silicon germanium, silicon carbide, Group III nitride (e.g., including indium, gallium, and/or aluminum nitride), or glass wafer. As shown in FIG. 6A2, the semiconductor wafer 114W is thinned to a desired thickness T2, providing a thinned semiconductor wafer 114W’. For example, the semiconductor wafer 114W may be thinned using a chemical-mechanical polishing (CMP) or other thinning process. The thinned semiconductor wafer 114W’ may have a thickness T2 of about 50 µm to about 700 µm.

As shown in FIG. 6A3, a wide-bandgap material layer 112L is bonded to a surface of the thinned semiconductor wafer 114W’, for example, using a wafer-on-wafer bonding process. The bonding process provides a bonding interface 113 (e.g., a wafer-on-wafer bonding interface) between the thinned semiconductor wafer 114W’ and the wide-bandgap material layer 112L. The wide-bandgap material layer 112L may be a diamond (e.g., single crystal or polycrystalline diamond), aluminum nitride, boron nitride, gallium nitride, or silicon carbide layer or wafer. The thickness T1 of the wide-bandgap material layer 112L may be substantially thinner (e.g., more than about five times thinner) than the thickness T2 of the thinned semiconductor waver 114W’. For example, the wide-bandgap material layer 112L may have a thickness T1 of about 2 µm to about 100 µm (e.g., about 2 µm to about 50 µm). The thinned semiconductor wafer 114W’ and the wide-bandgap material layer 112L bonded thereto provide a thermally conductive lid layer 110L.

As shown in FIG. 6B1, a semiconductor wafer 105W is similarly bonded to or otherwise provided on a carrier wafer 602. The semiconductor wafer 105W may include an active layer 104 between opposing first and second surfaces 105S1, 105S2. The semiconductor wafer 105W may include EIC and/or PIC devices. For example, the semiconductor wafer 105W may be a silicon, silicon germanium, silicon carbide, Group III nitride (e.g., including indium, gallium, and/or aluminum nitride) wafer. The semiconductor wafer 114W and the semiconductor wafer 105W may include one or more of the same materials, for example, for process compatibility and ease of manufacture.

As shown in FIG. 6B2, the semiconductor wafer 105W is thinned to a desired thickness, providing a thinned semiconductor wafer 105W’. For example, the semiconductor wafer 105W may be thinned using a CMP or other thinning process. The thickness of the EIC or PIC wafer may be about 50 µm or less (e.g., about 10 µm or less) in some embodiments.

As shown in 6C, the thermally conductive lid layer 110L is bonded or otherwise attached to the thinned semiconductor wafer 105W’. In particular, the wide-bandgap material layer 112L is bonded to the first surface 105S1 of the thinned semiconductor wafer 105W’, for example, using a wafer-on-wafer bonding process. The bonding process provides a bonding interface 107 (e.g., a wafer-on-wafer bonding interface) between the wide-bandgap material layer 112L and the thinned semiconductor wafer 105W’. The wide-bandgap material layer 112L is thus bonded to the first surface 105S1 of the thinned semiconductor wafer 105W’ (at bonding interface 107), and the thinned semiconductor wafer 114W’ is bonded to the wide-bandgap material layer 112L opposite the first surface 105S1. In embodiments where the thinned semiconductor wafer 114W’ is a silicon wafer and the wide-bandgap material layer 112L is a single crystal diamond (SCD) layer, the bonding process of FIG. 6C results in a EIC/PIC-SCD-Si wafer.

As shown in FIG. 6D, the carrier substrate 601 is removed and a die singulation process is performed to singulate the semiconductor wafer 105W’ having the thermally conductive lid layer 110L thereon. The die singulation process results in a plurality of semiconductor dies 105 having respective thermally conductive lids 110 thereon, thereby forming the integrated circuit devices 100 of FIGS. 1A-1E.

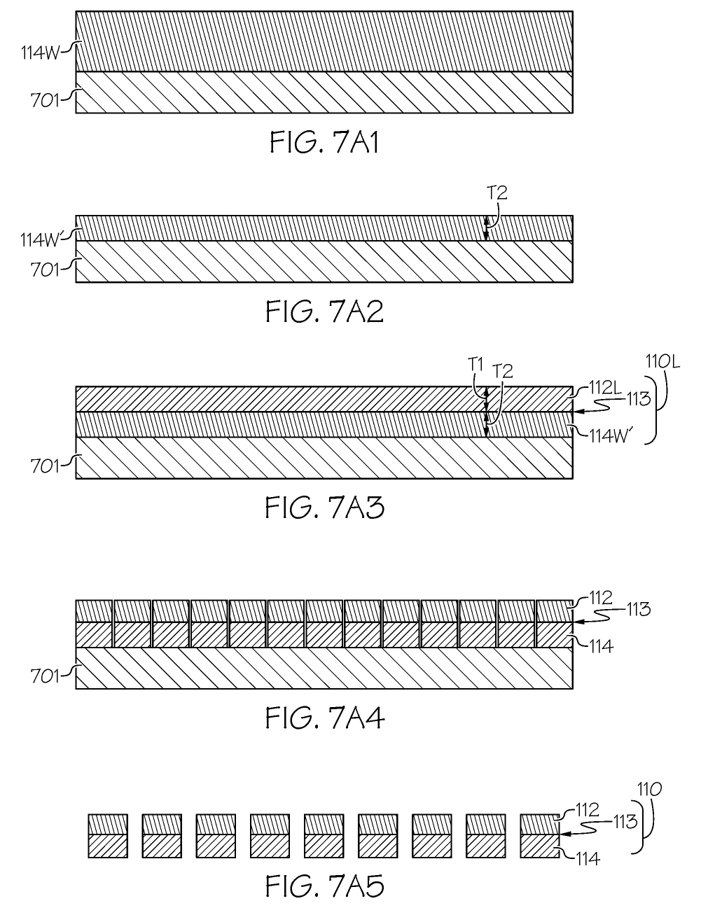

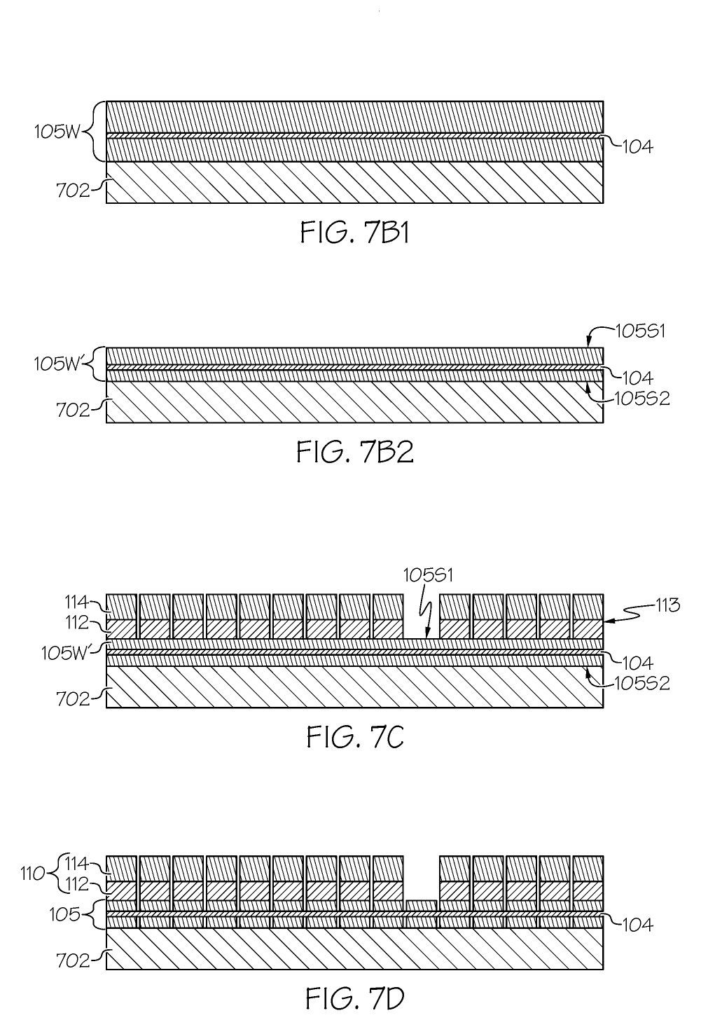

FIGS. 7A1, 7A2, 7A3, 7A4, 7A5, 7B1, 7B2, 7C, and 7D (collectively, FIG. 7) are schematic cross-sectional view diagrams illustrating methods of fabricating integrated circuit devices including semiconductor dies and thermally conductive lids using die-on-wafer (DoW) bonding according to some embodiments of the present disclosure. Die-on-wafer bonding can include a semiconductor manufacturing process where individual dies or chiplets are attached and electrically connected to a larger wafer (e.g., also including dies or chiplets), DoW bonding may allow for heterogeneous integration of chips of different sizes, and may allow for high yield by using only known good dies (KGD), that is, dies that have already been electrically tested for functionality. DoW bonding may include adhesive bonding or hybrid bonding, where direct metal-to-metal and dielectric-to-dielectric connections can be made at low temperatures. The wafers and material layers shown in FIG. 7 may be similar to those described above with reference to FIG. 6 (with like elements labeled with like reference numbers), and repeated description thereof is omitted for brevity.

As shown in FIG. 7A1, a semiconductor wafer 114W is bonded to or otherwise provided on a carrier wafer 701. As shown in FIG. 7A2, the semiconductor wafer 114W is thinned (e.g., using CMP or other thinning process) to a desired thickness T2, providing a thinned semiconductor wafer 114W’. As shown in FIG. 7A3, a wide-bandgap material layer 112L is bonded to a surface of the thinned semiconductor wafer 114W’, for example, using a wafer-on-wafer bonding process. The bonding process provides a bonding interface 113 (e.g., a wafer-on-wafer bonding interface) between the thinned semiconductor wafer 114W’ and the wide-bandgap material layer 112L. The thickness T1 of the wide-bandgap material layer 112L may be substantially thinner (e.g., more than about five times thinner) than the thickness T2 of the thinned semiconductor waver 114W’. The thinned semiconductor wafer 114W’ and the wide-bandgap material layer 112L bonded thereto provide a thermally conductive lid layer 110L.

As shown in FIG. 7A4, a singulation process is performed to singulate the thermally conductive lid layer 110L into respective thermally conductive lids 110 of desired sizes (e.g., die-sized or chiplet-sized), which may (in some embodiments) be freed from the carrier substrate 701, as shown in FIG. 7A5. The respective thermally conductive lids 110 each include the wide bandgap material layer 112 bonded to a semiconductor layer 114. In embodiments where the thinned semiconductor wafer 114W’ is a silicon wafer and the wide-bandgap material layer 112L is a single crystal diamond (SCD) layer, the processes of FIG. 7A4 and FIG. 7A5 provide individual SCD-Si lids.

As shown in FIG. 7B1, a semiconductor wafer 105W (which may include EIC and/or PIC devices) is similarly bonded to or otherwise provided on a carrier wafer 702. The semiconductor wafer 114W and the semiconductor wafer 105W may include one or more of the same materials, for example, for process compatibility and ease of manufacture. The semiconductor wafer 105W may include an active layer 104 between opposing first and second surfaces 105S1, 105S2. As shown in FIG. 7B2, the semiconductor wafer 105W is thinned (e.g., using CMP or other thinning process) to a desired thickness, providing a thinned semiconductor wafer 105W’.

As shown in FIG. 7C, the respective thermally conductive lids 110 are bonded or otherwise attached to the thinned semiconductor wafer 105W’. In particular, the wide-bandgap material layer 112 of each thermally conducive lid 110 is bonded to the first surface 105S1 of the thinned semiconductor wafer 105W’, for example, using a die-on-wafer bonding process. The bonding process provides a respective bonding interface 107 (e.g., a die-on-wafer bonding interface) between each wide-bandgap material layer 112 and the thinned semiconductor wafer 105W’.

In greater detail, the respective thermally conductive lids 110 may be bonded to each known good die (KGD) of the thinned semiconductor wafer 105W’ (including EICs and/or PICs) using a die-on-wafer bonding process. The KGD may be identified during a EIC/PIC wafer testing, which may be performed before attaching the respective thermally conductive lids 110 to the thinned semiconductor wafer 105W’. That is, the respective thermally conductive lids 110 may be bonded to respective portions of the first surface 105S1 of the thinned semiconductor wafer 105W’ with respective first bonding interfaces 107 therebetween. In some embodiments, the respective thermally conductive lids 110 may be transferred to the thinned semiconductor wafer 105W’ (also referred to as a target wafer) by direct placement die-to-wafer bonding (DP-D2W), where individual thermally conductive lids 110 are picked up and bonded directly to the target wafer 105W’ one by one.

As shown in FIG. 7D, a die singulation process is performed to singulate the semiconductor wafer 105W’ having the respective thermally conductive lids 110 thereon. The die singulation process results in a plurality of semiconductor dies 105 having respective thermally conductive lids 110 thereon (e.g., EIC/PIC-SCD-Si chiplets), thereby forming the integrated circuit devices 100 of FIGS. 1A-1E.

The fabrication operations of FIG. 7 may be used, for example, in embodiments where the size of the semiconductor wafer 114W does not match with the size of the semiconductor wafer 105W (i.e., with respect to planar surface area), such that a WoW process may not be easily or efficiently performed. The fabrication operations of FIG. 7 may also be used if the semiconductor wafer 105W (including the EICs/PICs) has a relatively low yield, such that bonding the individual thermally conductive (e.g., SCD-Si) lids 110 lid only to the KGD of the semiconductor wafer 105W may reduce cost (as the thermally conductive lids 110 may not be provided on defective semiconductor dies 105).

Although simplified for purposes of illustration, it will be understood that the fabrication operations of FIGS. 6 and 7 may be applied and/or modified to fabricate any of the integrated circuit devices 100a-100e of FIGS. 1A-1E. For example, in some embodiments the semiconductor wafer 105W may include one or more PICs, BSPDNs, or I/O elements, such that the fabrication operations of FIGS. 6 and/or 7 may provide the integrated circuit devices 100a, 100c, and 100e of FIGS. 1A, 1C, and 1E, respectively. As another example, prior to bonding the thermally conductive lid layer 110L or thermally conductive lids 110 to the thinned semiconductor wafer 105W’ in FIGS. 6C or 7C, a memory cell wafer (including one or more layers or stacks of memory cell transistors) may be bonded to the thinned semiconductor wafer 105W’, such that the fabrication operations of FIGS. 6 and/or 7 may provide the integrated circuit devices 100d of FIG. 1D.

The individual integrated circuit devices 100a-100e (each including a semiconductor die 105 and a thermally conductive lid 110 thereon) may be embedded in a package substrate or attached to a surface thereof, to provide advanced integrated circuit packages with improved thermal performance (e.g., greater heat dissipation and/or reduced hot spots). Further embodiments of the present disclosure are directed to package assembly processes that may be used to fabricate the integrated circuit packages of FIGS. 2A-5. While illustrated by way of example with reference to fabricating the integrated circuit packages 200 and 300 of FIGS. 2A/2B and 3A/3B, it will be understood that these assembly processes may be applied and/or modified to form any of the integrated circuit packages 200, 200’, 300, 400, 500 of FIGS. 2A/2B, 2C, 3A/3B, 4, and 5.

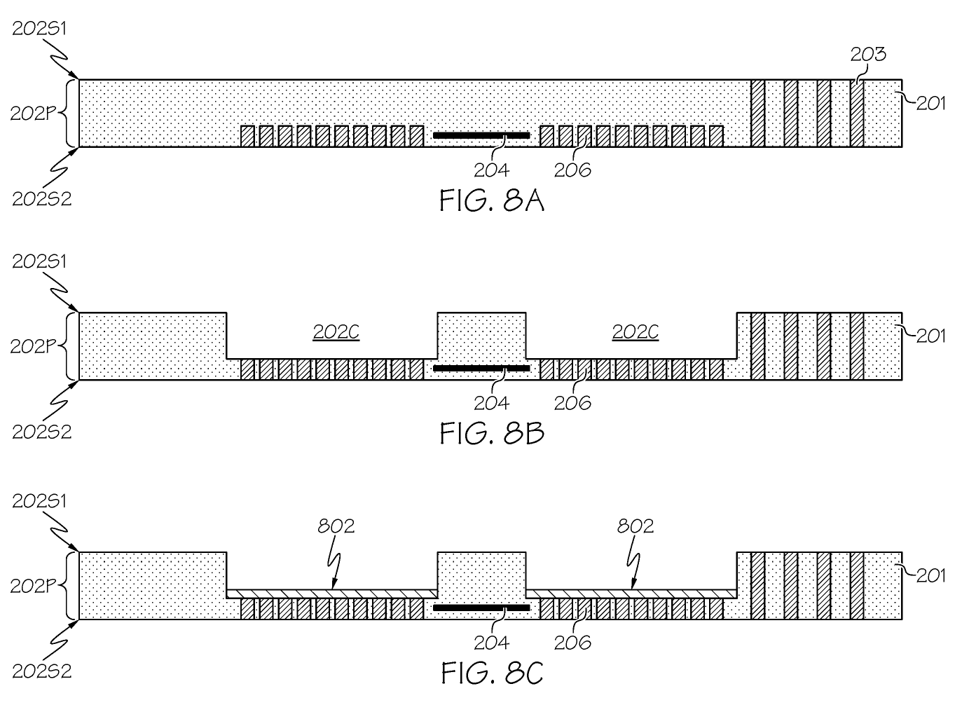

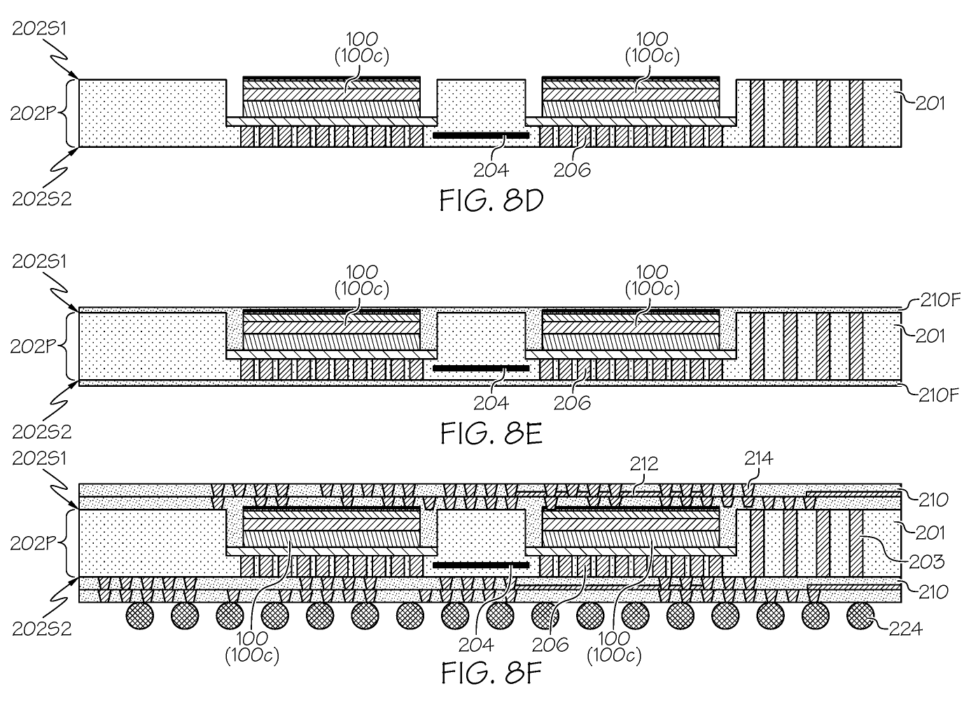

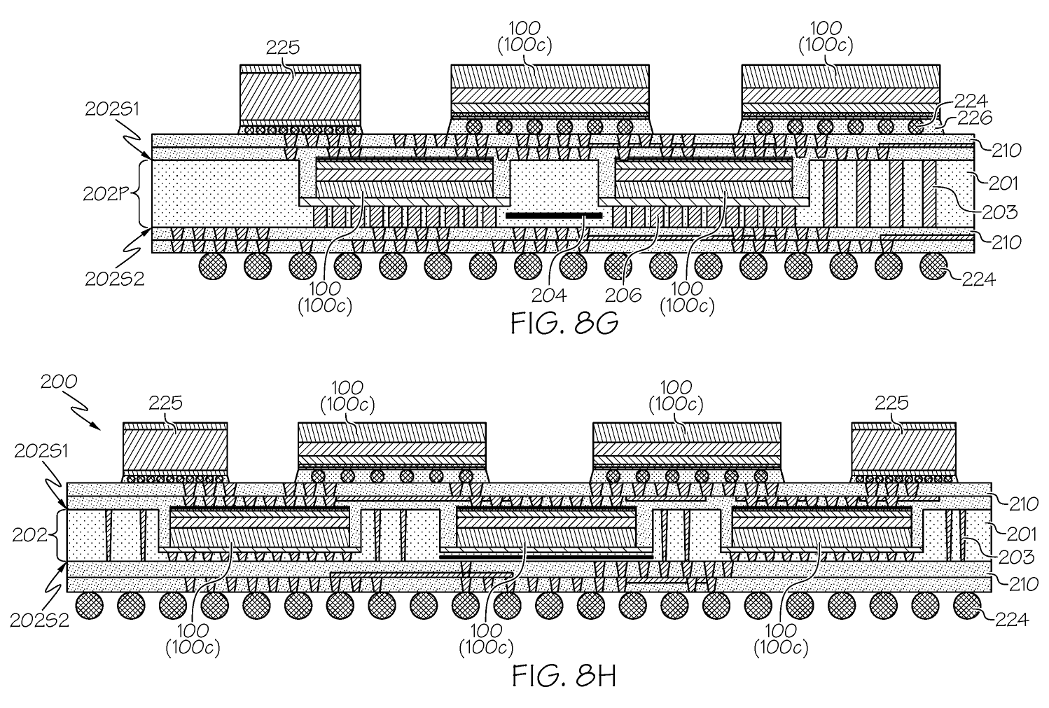

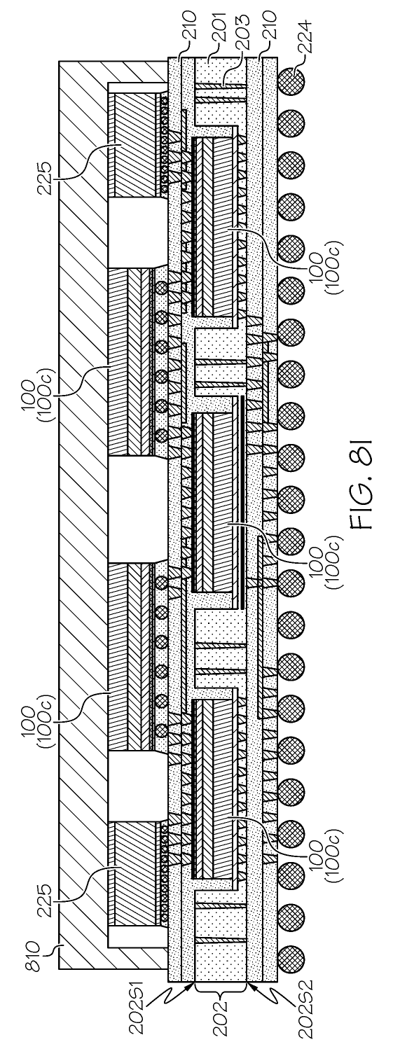

FIGS. 8A, 8B, 8C, 8D, 8E, 8F, 8G, 8H, and 8I (collectively, FIG. 8) are schematic cross-sectional view diagrams illustrating methods of fabricating integrated circuit device packages (illustrated with reference to the integrated circuit device package 200 of FIG. 2A/2B) including integrated circuit devices attached on and/or embedded in a package substrate according to some embodiments of the present disclosure. In particular, FIGS. 8A-8I schematically illustrates a process flow, according to some example embodiments of the present disclosure, for forming advanced packages including semiconductor dies 105 having respective thermally conductive lids 110 thereon (e.g., EIC/PIC-SCD-Si chiplets with BSPDNs) embedded in a package substrate 202. The package substrates 202 may be at panel or wafer scale.

As shown in FIG. 8A, a package substrate panel or wafer 202P is provided. The package substrate panel or wafer 202P may include a glass, Si, or organic core layer 201 in some embodiments. The package substrate panel or wafer 202P may include liquid cooling channels 204, thermally conductive vias 206, and electrically conductive through vias 203 (such as through-glass vias (TGV), through-silicon vias (TSV), or through-organic vias (TOV)) inside the core layer 201 between a top surface 202S1 and a bottom surface 202S2.

As shown in FIG. 8B, cavities 202C are formed in the package substrate panel or wafer 202P, for example, using laser milling or wet etching technique at a panel or wafer scale. That is, the top surface 202S1 of the package substrate panel or wafer 202P is recessed to form a cavity 202C extending below the top surface 202S1. The cavities 202Cmay be formed such that the liquid cooling channels 204 and/or thermal vias 206 extend under or adjacent to the cavities 202C.

As shown in FIG. 8C, die backside films 802 are laminated or otherwise provided on a bottom surface or floor of the respective cavities 202C. Respective integrated circuit devices 100 (shown by way of example as the integrated circuit devices 100c of FIG. 1C) are attached to the floor of the respective cavities 202C in FIG. 8D by the die backside films 802. The integrated circuit devices 100 may include semiconductor dies 105 having respective thermally conductive lids 110 thereon (e.g., EIC/PIC-SCD-Si chiplets with BSPDNs), with the semiconductor material second layer 114 facing the die backside films 802.

As shown in FIG. 8E, one or more build-up films or RDL dry films 210F are laminated or otherwise attached on top and bottom surfaces 202S1 and 202S2 of the package substrate panel or wafer 202P, as well as in open spaces in the cavities 202C. In FIG. 8F, lithography may be used to create conductive lines 212 and conductive vias 214 in/on the build-up films or RDL dry films to form redistribution layers 210, as well as conductive joints or bumps 224 on the redistribution layers 210 adjacent to the bottom surface 202S2 of the package substrate panel or wafer 202P.

As shown in FIG. 8G, one or more integrated circuit devices 100 (along with additional components, shown as memory dies 225) are attached to the top surface 202S1 of the package substrate panel or wafer 202P (e.g., by conductive joints 224 (such as solder balls or conductive pillars) with underfill layers 226 therebetween). Other components (such as HBMs, ASIC (with BSPDN), or other chiplets described herein) may be similarly assembled on and attached to the top surface 202S1 at a wafer or panel level.

As shown in FIG. 8H, the package substrate panel or wafer 202P may be singulated into respective units to provide integrated circuit device packages 200, each including a respective package substrate 202, as shown in FIGS. 2A-2B. In some embodiments, as shown in FIG. 8I, a thermal interface material (TIM) and/or thermally conductive (e.g., copper) lid or heat sink 810 may be attached to the integrated circuit devices 100c and/or memory dies 225 of a respective integrated circuit device package 200, opposite the package substrate 202. While illustrated with reference to attaching and embedding the integrated circuit devices 100c of FIG. 1C, it will be understood that one or more operations shown in FIG. 8 can be similarly used for attaching or embedding any of the integrated circuit devices 100a-100e of FIGS. 1A-1E.

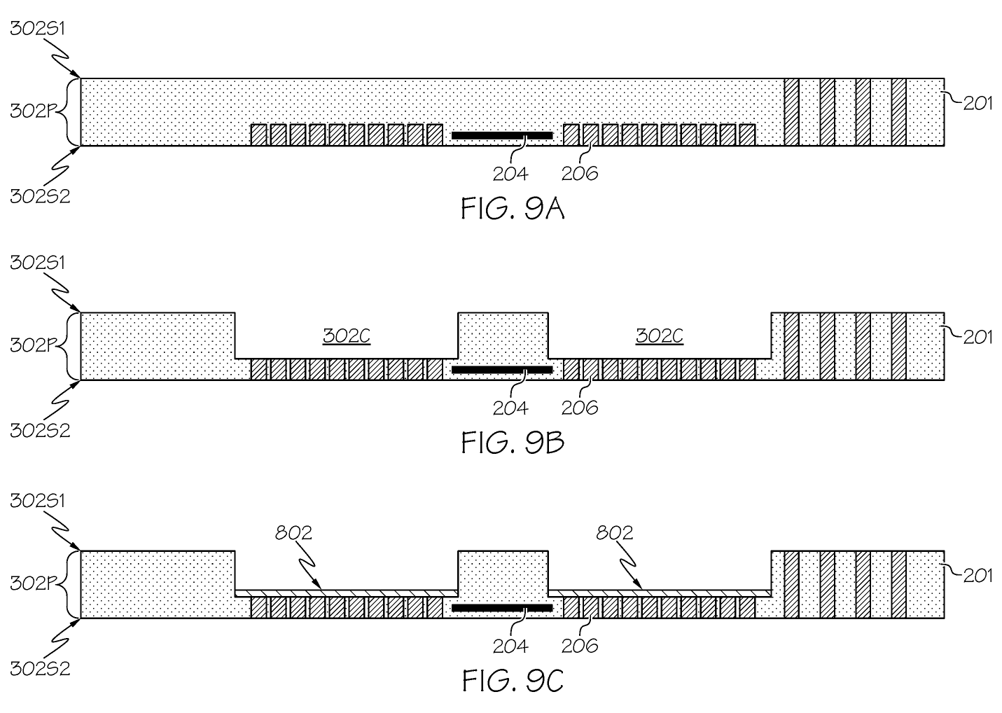

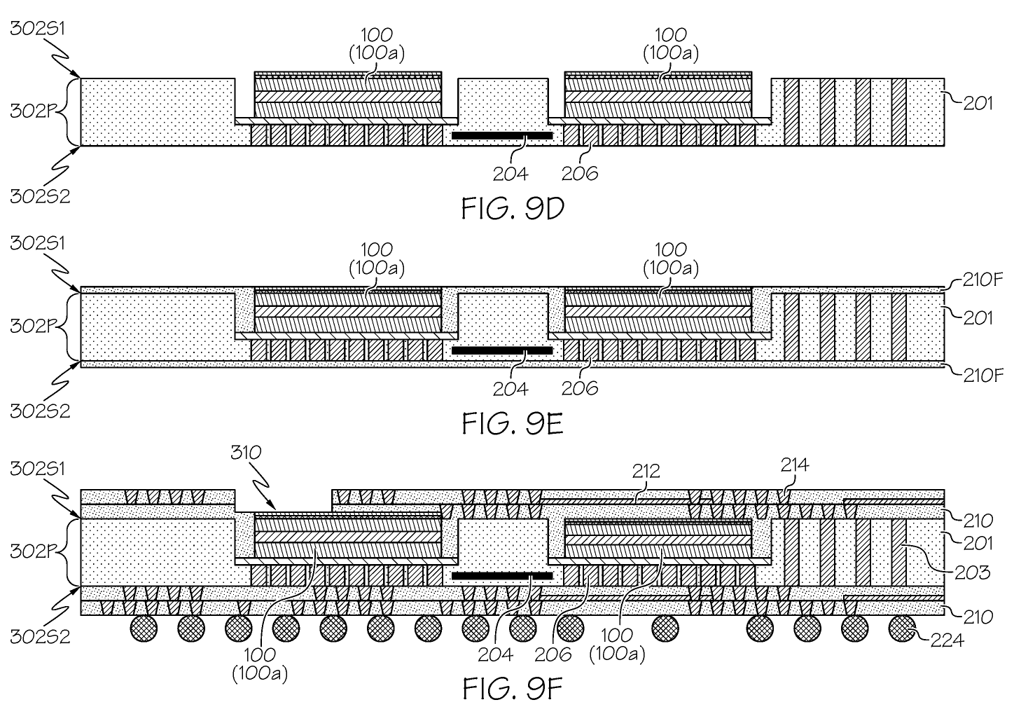

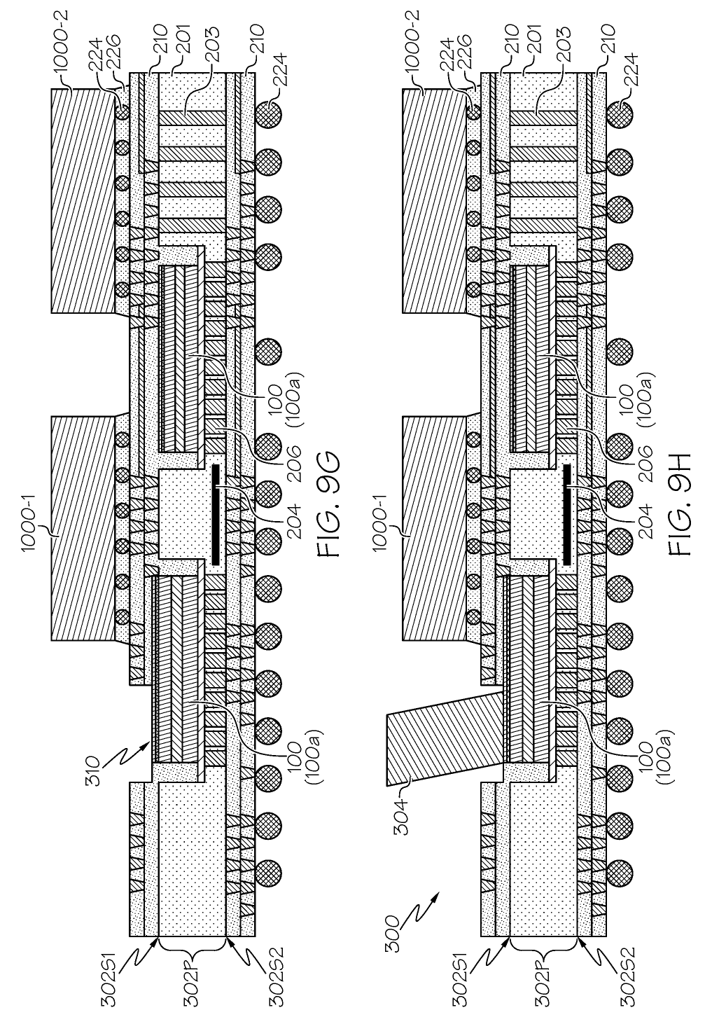

FIGS. 9A, 9B, 9C, 9D, 9E, 9F, 9G, and 9H (collectively, FIG. 9) are schematic cross-sectional view diagrams illustrating methods of fabricating integrated circuit device packages (illustrated with reference to the integrated circuit device package 300 of FIG. 3A/3B) including integrated circuit devices embedded in a package substrate according to some embodiments of the present disclosure. In particular, FIGS. 9A-9H schematically illustrates a process flow, according to some example embodiments of the present disclosure, for forming advanced packages including semiconductor dies 105 having respective thermally conductive lids 110 thereon (e.g., PIC-SCD-Si chiplets or active bridges) embedded in a package substrate 302. The package substrates 302 may be at panel or wafer scale.

As shown in FIG. 9A, a package substrate panel or wafer 302P is provided. The package substrate panel or wafer 302P may include a glass, Si, or organic core layer 201 in some embodiments. The package substrate panel or wafer 302Pmay include liquid cooling channels 204, thermally conductive vias 206, and electrically conductive through vias 203 (such as through-glass vias (TGV), through-silicon vias (TSV), or through-organic vias (TOV)) inside the core layer 201 between a top surface 302S1 and a bottom surface 302S2.

As shown in FIG. 9B, cavities 302C are formed in the package substrate panel or wafer 302P, for example, using laser milling or wet etching technique at a panel or wafer scale. That is, the top surface 302S1 of the package substrate panel or wafer 302P is recessed to form a cavity 302C extending below the top surface 302S1. The cavities 302Cmay be formed such that the liquid cooling channels 204 and/or thermal vias 206 extend under or adjacent to the cavities 302C.

As shown in FIG. 9C, die backside films 802 are laminated or otherwise provided on a bottom surface or floor of the respective cavities 302C. Respective integrated circuit devices 100 (shown by way of example as the PIC devices 100a of FIG. 1A) are attached to the floor of the respective cavities 302C in FIG. 9D by the die backside films 802. The integrated circuit devices 100 may include semiconductor dies 105 having respective thermally conductive lids 110 thereon (e.g., PIC-SCD-Si chiplets), with the semiconductor material second layer 114 facing the die backside films 802.

As shown in FIG. 9E, one or more build-up films or RDL dry films 210F are laminated or otherwise attached on top and bottom surfaces 302S1 and 302S2 of the package substrate panel or wafer 302P, as well as in open spaces in the cavities 302C. In FIG. 9F, lithography may be used to create conductive lines 212 and conductive vias 214 in/on the build-up films or RDL dry films 210F to form redistribution layers 210, as well as conductive joints or bumps 224 on the redistribution layers 210 adjacent to the bottom surface 302S2 of the package substrate panel or wafer 302P. In addition, at least one opening 310 is formed in the redistribution layers 210 adjacent to the top surface 302S1 of the package substrate panel or wafer 302P. The opening 310 exposes at least one of the embedded integrated circuit devices 100a in the cavities 302C.

As shown in FIG. 9G, one or more components 1000-1 and 1000-2 (which in some embodiments may be or may include the integrated circuit devices 100 described herein) are attached to the top surface 302S1 of the package substrate panel or wafer 302P (e.g., by conductive joints 224 (such as solder balls or conductive pillars) with underfill layers 226 therebetween). Other components (such as HBMs, ASIC (with BSPDN), or other chiplets described herein) may be similarly assembled on and attached to the top surface 302S1 at a wafer or panel level.

As shown in FIG. 9H, a fiber optic array unit (FAU) 304 is provided in the opening 310 and is optically coupled to PIC device 100a. The FAU 304 is configured to align multiple optical fibers for connection to the PIC device 100a. The package substrate panel or wafer 302P may be subsequently singulated into respective units to provide integrated circuit device packages 300, each including a respective package substrate 302, as shown in FIGS. 3A-3B. In some embodiments, a TIM and/or thermally conductive (e.g., copper) lid or heat sink may be attached to the respective integrated circuit device packages 300.

Embodiments of the present disclosure may thereby embed semiconductor dies having respective thermally conductive lids thereon (e.g., EIC/PIC-SCD-Si chiplets) into a package substrate (e.g., glass or Si substrates) with redistribution layers thereon. Compared to packages with glass or Si substrates of comparative examples, some embodiments of the present disclosure can effectively reduce hot spots in the embedded and stacked chiplets, thereby improving performance. In addition, by utilizing multi-layer thermally conductive lids (e.g., including a wide-bandgap material layer (such as SCD) and a narrower bandgap semiconductor material layer stacked thereon), the thickness of the SCD (or other wide-bandgap material) layer may be reduced without reducing performance, thereby reducing costs. Additionally, by utilizing a semiconductor layer of the same material as the PIC and/or EIC dies, thermally conductive lids according to some example embodiments of the present disclosure can be easily integrated into die embedding and stacking techniques and processes.

According to some example embodiments of the present disclosure, an integrated circuit device or package may include diamond to help with thermal management. For example, an EIC or PIC chip or chiplet may be bonded to a SCD layer and may be embedded in glass or Si substrates. The SCD layer may be a thermal lid only, without electrical connections or through diamond vias (TDVs) therein. According to some example embodiments of the present disclosure, a manufacturing method may include bonding an SCD layer to an Si layer or a glass layer to provide a thermally conductive lid, bonding the thermally conductive lid to EIC or PIC chips or chiplets, and embedding the chips or chiplets having the thermally conductive lid thereon into a package substrate using a die embedding assembly process.

In particular embodiments of the present disclosure, a semiconductor device, package, and manufacturing methods thereof may include an Si lid layer bonded to the backside of a thin SCD lid layer to provide a (thermally conductive) SCD-Si lid. The SCD-Si lid may be bonded to EIC or PIC chips or chiplets. The SCD-Si bonded chips or chiplets can be embedded into or attached to a top and/or bottom surface of a glass or Si package substrate to provide large 2.5D or 3D packages with improved thermal performance. Additionally, SCD-Si bonded PIC and active bridge dies can be embedded into the Si or glass substrates to provide advanced CPO packages with improved heat dissipation for the embedded dies.

Package architectures including semiconductor chips or chiplets with thermally conductive lids according to some embodiments of the present disclosure may provide several advantages. In particular, bonding the SCD (or other wide-bandgap thermally conductive material) layer close to the transistor or active layers of an EIC or PIC may provide efficient and effective thermal solutions for quickly dissipating hot spots in the chips or chiplets of complex 2.5D or 3D packages, which can improve device performance. Also, bonding a thin Si (or other semiconductor material) layer on the backside of SCD may provide compatibility with die embedding and die stacking processes developed for Si (or other semiconductor) chips, and may reduce cost (by reducing the SCD thickness) without decreasing performance. Implementation of thermally conductive lids on ASICs that include BSPDNs can separate the PDN from the signal network, which can improve PDN performance. In particular, bonding the SCD (or other wide-bandgap material) layer of the thermally conductive lid near the active layer of ASIC (i.e., on an opposite surface from the BSPDN) can resolve hot spot issues and can provide process compatibility for die embedding and stacking of the ASIC with BSPDN. Moreover, memory chips, including cache, static random-access memory (SRAM), dynamic random-access memory (DRAM), and HBM may be directly integrated to the signal layers of ASIC with BSPDN, before bonding to the thermally conductive lid, which may provide faster memory access with lower power consumption, wider bandwidth, and higher capacity without (or with reduced) hot spot induced issues. With respect to package substrates, Si and glass materials can be implemented in the assembly to generate larger packages with improved performance, e.g., due to the stiffness of and/or superior electrical properties of Si and glass. Liquid cooling channels and/or thermal vias can be provided inside the package substrates to further improve thermal performance, and integrated stacked capacitors (ISC) can be embedded inside the package substrates to further improve PDN performance.

Embodiments of the present disclosure may include various applications, for example (but not limited to) AI, CPU, GPU, AI, chips and/or other ASICs that may require a large amount of power; automotive and/or radio-frequency (RF) chips that may require higher reliability in harsh environments or use conditions; and datacenter applications that may require larger package dimensions. More generally, some embodiments of the present disclosure may include diamond, single crystal diamond (SCD), backside power delivery networks (BSPDNs), application-specific integrated circuits (ASICs), advanced packaging, three-dimensional (3D) integrated circuits (ICs), 2.5D ICs, glass substrates, silicon (Si) substrates, electronic integrated circuits (EICs), photonic integrated circuits (PICs), co-packaged optics (CPOs), embedding, panel-level packaging (PLP), wafer-level packaging (WLP), and/or integrated stack capacitors (ISCs).

The disclosure herein is presented to enable one of ordinary skill in the art to make and use the disclosure and to incorporate it in the context of particular applications. While the foregoing is directed to specific examples, other and further examples may be devised without departing from the basic scope thereof.

Various modifications, as well as a variety of uses in different applications will be readily apparent to those skilled in the art, and the general principles defined herein may be applied to a wide range of embodiments. Thus, the present disclosure is not intended to be limited to the embodiments presented, but is to be accorded the widest scope consistent with the principles and novel features disclosed herein.

In the description provided, numerous specific details are set forth in order to provide a more thorough understanding of the present disclosure. However, it will be apparent to one skilled in the art that the present disclosure may be practiced without necessarily being limited to these specific details. In other instances, well-known structures and devices are shown in block diagram form, rather than in detail, in order to avoid obscuring the present disclosure.

Features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein.

In the description above, example embodiments may be described with reference to regions of particular conductivity types (e.g., n-type and p-type). It will be appreciated that opposite conductivity type devices may be formed by simply reversing the conductivity of the n-type and p-type layers in each of the above embodiments. Thus, it will be appreciated that the present disclosure covers both n-channel and p-channel devices for each different device structure.

The terminology used herein is for the purpose of describing particular embodiments only and is not intended to be limiting of embodiments. The singular forms “a,” “an,” and “the” are intended to include the plural forms as well, unless the context clearly indicates otherwise. The terms “comprises,” “comprising,” “includes” and/or “including” specify the presence of the stated features, steps, operations, elements, components and/or groups, but do not preclude the presence or addition of one or more other features, steps, operations, elements, components and/or groups thereof.

It will be understood that, although the terms “first,” “second,” etc. may be used throughout this specification to describe various elements, these elements should not be limited by these terms. Rather, these terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terms “surround” or “cover” or “fill” as used herein may not require completely surrounding or covering or filling the described elements or layers, but may, for example, refer to partially surrounding or covering or filling the described elements or layers. Components or layers described with reference to “overlap” in a particular direction may be at least partially obstructed by one another when viewed along a line extending in the particular direction or in a plane perpendicular to the particular direction.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. The term “connected” may include physical and/or electrical connections.

Spatially relative terms such as “below” or “above” or “upper” or “lower” or “top” or “bottom” or “side” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures. As used herein, the terms “frontside” and “backside” can include opposite sides (e.g., top and bottom) of an integrated circuit device, with frontside layers or structures being above the transistor structures, and backside layers or structures being below the transistor structures as shown in the figures.

Example embodiments are described herein with reference to the accompanying drawings, which may include cross-section illustrations that are schematic illustrations of idealized embodiments (and intermediate structures). Many different forms and embodiments are possible without deviating from the teachings of this disclosure. Accordingly, the present disclosure should not be construed as limited to the example embodiments set forth herein. As such, it will be understood by those of ordinary skill in the art that various changes in form and details may be made therein without departing from the scope as defined herein. In the drawings, the sizes and relative sizes of layers and regions may be exaggerated for clarity. Additionally, variations from the shapes of the illustrations as a result, for example, of manufacturing techniques and/or tolerances, are to be expected.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope is to be determined by the broadest permissible interpretation of the following claims and their equivalents, and shall not be restricted or limited by the foregoing detailed description.

1. An integrated circuit device, comprising:
a semiconductor die comprising an active layer between opposing first and second surfaces; and
a thermally conductive lid that is external to the semiconductor die, the thermally conductive lid comprising a first layer of a first material on the first surface of the semiconductor die and a second layer of a second material on the first layer opposite the first surface, wherein the first material has a wider bandgap than the second material.

2. The integrated circuit device of claim 1, wherein the first material comprises a wide-bandgap material having an energy bandgap of greater than about 2 electron-volts, and the second material comprises a semiconductor material.

3. The integrated circuit device of claim 1, wherein a surface of the active layer is a first distance from the first surface and is a second distance from the second surface, wherein the first distance is smaller than the second distance.

4. The integrated circuit device of claim 1, wherein the semiconductor die comprises the second material.

5. The integrated circuit device of claim 1, wherein the first layer has a first thickness of about 2 µm to about 100 µm, and the second layer has a second thickness of about 50 µm to about 700 µm.

6. The integrated circuit device of claim 1, wherein the semiconductor die further comprises a backside power delivery network adjacent to the second surface thereof.

7. The integrated circuit device of claim 6, wherein the semiconductor die further comprises a memory chip between the backside power delivery network and the thermally conductive lid.

8. The integrated circuit device of claim 6, wherein the semiconductor die comprises a photonic integrated circuit (PIC) or an electronic integrated circuit (EIC).

9. The integrated circuit device of claim 1, wherein the first material comprises diamond, aluminum nitride, boron nitride, gallium nitride, or silicon carbide, and the second material comprises glass, silicon, gallium nitride, or silicon carbide.

10. An integrated circuit device package, comprising:
a package substrate; and
an integrated circuit device adjacent to a surface of the package substrate, the integrated circuit device comprising:
a semiconductor die comprising an active layer between opposing first and second surfaces; and
a thermally conductive lid that is external to the semiconductor die, the thermally conductive lid comprising a first layer of a first material on the first surface of the semiconductor die and a second layer of a second material on the first layer opposite the first surface, wherein the first material has a wider bandgap than the second material,
wherein the semiconductor die is between the thermally conductive lid and the surface of the package substrate.

11. The integrated circuit device package of claim 10, wherein the first material comprises a wide-bandgap material having an energy bandgap of greater than about 2 electron-volts, and the second material comprises a semiconductor material.

12. The integrated circuit device of claim 10, wherein the first material comprises diamond, and the active layer comprises the second material.

13. The integrated circuit device package of claim 10, wherein the integrated circuit device is embedded in the package substrate below the surface thereof.

14. The integrated circuit device package of claim 13, wherein the package substrate further comprises one or more redistribution layers on the second surface of the semiconductor die, wherein the one or more redistribution layers comprises conductive lines and vias,
wherein the semiconductor die and the conductive lines and vias are electrically connected to first and second components that are attached to the surface of the package substrate.

15. The integrated circuit device package of claim 13, further comprising:
liquid cooling channels and/or thermal vias in the package substrate extending under or adjacent to the thermally conductive lid of the integrated circuit device.

16. The integrated circuit device package of claim 10, wherein the semiconductor die comprises a photonic integrated circuit, and further comprising:
a fiber optic array unit that is optically coupled to the photonic integrated circuit at the second surface of the semiconductor die.

17. The integrated circuit device package of claim 10, wherein the semiconductor die further comprises a backside power delivery network adjacent to the second surface.

18. The integrated circuit device package of claim 10, wherein the integrated circuit device is a first integrated circuit device and the surface of the package substrate is a top surface, and further comprising:
a second integrated circuit device attached to a bottom surface of the package substrate that is opposite the top surface.

19. A method of fabricating an integrated circuit device package, the method comprising:
forming a thermally conductive lid layer by bonding a first layer of a first material to a second layer of a second material, wherein the first material has a wider bandgap than the second material; and
providing the thermally conductive lid layer on a semiconductor wafer comprising an active layer between opposing first and second surfaces, wherein the first layer is on the first surface of the semiconductor wafer and the second layer is on the first layer opposite the first surface.

20. The method of claim 19, wherein the first material comprises a wide-bandgap material having an energy bandgap of greater than about 2 electron-volts, and the second material comprises a semiconductor material.

21. The method of claim 19, wherein providing the thermally conductive lid layer on the semiconductor wafer comprises bonding the first layer of the thermally conductive lid layer to the first surface of the semiconductor wafer along a first bonding interface therebetween, and further comprising:
singulating the semiconductor wafer having the thermally conductive lid layer thereon to provide a plurality of semiconductor dies having respective thermally conductive lids thereon.

22. The method of claim 19, wherein providing the thermally conductive lid layer on the semiconductor wafer comprises:
singulating the thermally conductive lid layer into respective thermally conductive lids;
bonding the respective thermally conductive lids to respective portions of the first surface of the semiconductor wafer along respective first bonding interfaces therebetween; and
singulating the semiconductor wafer having the respective thermally conductive lids thereon to provide a plurality of semiconductor dies having the respective thermally conductive lids thereon.

23. The method of claim 19, wherein the semiconductor wafer comprises a first wafer having a backside power delivery network adjacent to the second surface.

24. The method of claim 23, wherein the semiconductor wafer further comprises a second wafer stacked on the first wafer, wherein the second wafer comprises a plurality of memory cell transistors between the backside power delivery network and the thermally conductive lid layer.

25. The method of claim 23, further comprising:
singulating the semiconductor wafer to provide an integrated circuit device comprising a semiconductor die having a thermally conductive lid thereon; and
providing the integrated circuit device adjacent to a surface of a package substrate.

26. The method of claim 25, wherein providing the integrated circuit device adjacent to the surface of the package substrate comprises:
recessing the surface of the package substrate to form a cavity extending below the surface; and
attaching the integrated circuit device to the package substrate in the cavity.
